(19) United States
(12) Patent Application Publication
(10) Pub. No.: US 2026/0150268 A1
(43) Pub. Date: May 28, 2026

(54) THREE-DIMENSIONAL MEMORY DEVICE AND METHOD FOR FORMING THE SAME

(71) Applicant: Yangtze Memory Technologies Co., Ltd., Wuhan (CN)

(72) Inventors: Zongliang Huo, Wuhan (CN); Wenbin Zhou, Wuhan (CN); Wei Xu, Wuhan (CN); Qiangwei Zhang, Wuhan (CN); Zongke Xu, Wuhan (CN)

(21) Appl. No.: 19/012,017

(22) Filed: Jan. 7, 2025

(30) Foreign Application Priority Data
Nov. 27, 2024 (WO) PCT/CN2024/134870
Nov. 29, 2024 (CN) 202411750556.2

(51) Int. Cl. H10B 12/00

(52) U.S. Cl. CPC H10B 12/395; H10B 12/0383; H10B 12/0387; H10B 12/50

(57) ABSTRACT

A memory device, a memory system, and a fabrication method are provided. The memory device includes a first semiconductor structure including a memory cell array in a memory array region of the first semiconductor structure. The memory cell array includes an array of transistors and an array of storage units which connect to corresponding transistors. The first semiconductor structure further includes an isolation structure surrounding the memory array region and isolating the array of storage units in the memory array region from a contact region of the first semiconductor structure.

### CROSS-REFERENCE TO RELATED APPLICATIONS

This application claims the benefit of priorities to Chinese Application No. 202411750556.2, filed on Nov. 29, 2024 and International Application No. PCT/CN 2024/134870, filed on Nov. 27, 2024, both of which are incorporated herein by reference in their entireties.

### TECHNICAL FIELD

The present disclosure generally relates to the field of semiconductor technology, and more particularly, to semiconductor devices and fabrication methods thereof.

### BACKGROUND

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In one aspect, a memory device includes a first semiconductor structure including a memory cell array in a memory array region of the first semiconductor structure. The memory cell array includes an array of transistors and an array of storage units which connect to corresponding transistors. The first semiconductor structure further includes an isolation structure surrounding the memory array region and isolating the array of storage units in the memory array region from a contact region of the first semiconductor structure.

In some implementations, the first semiconductor structure further includes a stack structure including alternating first layers and first dielectric layers in the contact region.

In some implementations, the first dielectric layers include a first dielectric material. The first layers include second dielectric layers that include a second dielectric material. The first dielectric material is different from the second dielectric material.

In some implementations, the first dielectric layers include a first dielectric material. The first layers include at least a second dielectric layer that includes a second dielectric material and a third dielectric layer that includes a third dielectric material. The first dielectric material, the second dielectric material, and the third dielectric material are different dielectric materials.

In some implementations, the first semiconductor structure further includes a dummy structure extending through the stack structure in the contact region in a first direction. An end surface of the dummy structure that is away from the array of transistors is flush with an end surface of the isolation structure that is away from the array of transistors.

In some implementations, the storage units include vertical capacitors, and the vertical capacitor includes: a first electrode structure coupled with a corresponding transistor; and a second electrode structure isolated from the first electrode structure. An end surface of the first electrode structure that is away from the array of transistors is flush with the end surface of the dummy structure.

In some implementations, a diameter of the end surface of the first electrode structure is equal to a diameter of the end surface of the dummy structure.

In some implementations, at least a part of a side wall of the isolation structure has a wavy shape.

In some implementations, in a cross section of one of the first dielectric layers perpendicular to the first direction, the isolation structure includes a first trench structure. A width of the first trench structure is greater than the diameter of the end surface of the first electrode structure.

In some implementations, in a cross section of one of the first layers perpendicular to the first direction, the isolation structure includes one or more sets of separate isolation members with each set of isolation members surrounding the memory array region. A diameter of the isolation member is equal to the diameter of the end surface of the first electrode structure and the diameter of the end surface of the dummy structure.

In some implementations, the width of the first trench structure is greater than n times of the diameter of the end surface of the first electrode structure, where n is a positive number equal to or greater than 2.

In some implementations, in a cross section of one of the first layers perpendicular to the first direction, the isolation structure includes a second trench structure. A width of the second trench structure is greater than the diameter of the end surface of the first electrode structure.

In some implementations, the width of the first trench structure and the width of the second trench structure are greater than n times of the diameter of the end surface of the first electrode structure, where n is a positive number equal to or greater than 2.

In some implementations, the isolation structure includes at least a gap structure.

In some implementations, in a cross section of one of the first layers perpendicular to the first direction, the second electrode structure is located between the adjacent first electrode structures.

In some implementations, the memory device further includes a second semiconductor structure bonded with the first semiconductor structure. The second semiconductor structure includes a peripheral circuit coupled with the memory cell array.

In another aspect, a memory device is disclosed. The memory device includes a first semiconductor structure including a memory cell array in a memory array region of the first semiconductor structure. The memory cell array includes an array of vertical transistors and an array of vertical capacitors which connect to corresponding vertical transistors. The first semiconductor structure further includes an isolation structure surrounding the memory array region and isolating the array of vertical capacitors in the memory array region from a contact region of the first semiconductor structure. At least a part of a side wall of the isolation structure has a wavy shape.

In some implementations, the first semiconductor structure further includes a stack structure including alternating first layers and first dielectric layers in the contact region.

In some implementations, the first dielectric layers include a first dielectric material, the first layers include second dielectric layers that include a second dielectric material, and the first dielectric material is different from the second dielectric material.

In some implementations, the first dielectric layers include a first dielectric material; the first layers include at least a second dielectric layer that includes a second dielectric material and a third dielectric layer that includes a third dielectric material; and the first dielectric material, the second dielectric material, and the third dielectric material are different dielectric materials.

In some implementations, the first semiconductor structure further includes a dummy structure extending through the stack structure in the contact region in a first direction. An end surface of the dummy structure that is away from the array of vertical transistors is flush with an end surface of the isolation structure that is away from the array of vertical transistors.

In some implementations, the vertical capacitor includes: a first electrode structure coupled with a corresponding transistor; and a second electrode structure isolated from the first electrode structure. An end surface of the first electrode structure that is away from the array of vertical transistors is flush with the end surface of the dummy structure.

In some implementations, a diameter of the end surface of the first electrode structure is equal to a diameter of the end surface of the dummy structure.

In some implementations, in a cross section of one of the first dielectric layers perpendicular to the first direction, the isolation structure includes a first trench structure. A width of the first trench structure is greater than the diameter of the end surface of the first electrode structure.

In some implementations, in a cross section of one of the first layers perpendicular to the first direction, the isolation structure includes one or more sets of separate isolation members with each set of isolation members surrounding the memory array region. A diameter of the isolation member is equal to the diameter of the end surface of the first electrode structure and the diameter of the end surface of the dummy structure.

In some implementations, the width of the first trench structure is greater than n times of the diameter of the end surface of the first electrode structure, where n is a positive number equal to or greater than 2.

In some implementations, in a cross section of one of the first layers perpendicular to the first direction, the isolation structure includes a second trench structure. A width of the second trench structure is greater than the diameter of the end surface of the first electrode structure.

In some implementations, the width of the first trench structure and the width of the second trench structure are greater than n times of the diameter of the end surface of the first electrode structure, where n is a positive number equal to or greater than 2.

In some implementations, the isolation structure includes at least a gap structure.

In some implementations, in a cross section of one of the first layers perpendicular to the first direction, the second electrode structure is located between the adjacent first electrode structures.

In some implementations, the memory device further includes a second semiconductor structure bonded with the first semiconductor structure. The second semiconductor structure includes a peripheral circuit coupled with the memory cell array.

In still another aspect, a method for forming a memory device is disclosed. The method includes forming a first semiconductor structure at least by forming a memory cell array in a memory array region of the first semiconductor structure. Forming the memory cell array includes forming an array of transistors in the memory array region, and forming, in the memory array region, an array of storage units which connect to corresponding transistors. Forming the first semiconductor structure further includes forming an isolation structure to surround the memory array region. The isolation structure isolates the array of storage units in the memory array region from a contact region of the first semiconductor structure.

In some implementations, forming the first semiconductor structure further includes forming a stack structure including alternating first layers and first dielectric layers across the memory array region and the contact region.

In some implementations, forming the first semiconductor structure further includes forming openings extending through the stack structure in a first direction. The openings include one or more sets of first openings between the memory array region and the contact region with each set of first openings surrounding the memory array region, a second opening in the contact region, and an array of third openings in the memory array region.

In some implementations, forming the isolation structure includes forming the isolation structure in the one or more sets of first openings.

In some implementations, forming the isolation structure in the one or more sets of first openings includes: in at least a first dielectric layer from the first dielectric layers, merging first portions of the first openings in the first dielectric layer to form a first trench opening, where a side wall of the first trench opening has a first wavy shape; and forming a first trench structure in the first trench opening of the first dielectric layer.

In some implementations, forming the isolation structure in the one or more sets of first openings further includes: in at least a first layer from the first layers, forming separate isolation members in second portions of the first openings in the first layer, respectively.

In some implementations, forming the isolation structure in the one or more sets of first openings further includes: in at least a first layer from the first layers, merging second portions of the first openings in the first layer to form a second trench opening, where a side wall of the second trench opening has a second wavy shape; and forming a second trench structure in the second trench opening of the first dielectric layer.

In some implementations, forming the first semiconductor structure further includes forming a dummy structure in the second opening. An end surface of the dummy structure that is away from the array of transistors is flush with an end surface of the isolation structure that is away from the array of transistors.

In some implementations, the storage units include vertical capacitors, and forming the array of storage units in the memory array region includes: forming first electrode structures in the third openings, respectively, where the first electrode structures are coupled with the transistors, respectively; and forming second electrode structures isolated from the first electrode structures. The vertical capacitor includes a corresponding first electrode structure and a corresponding second electrode structure.

In some implementations, forming the second electrode structures isolated from the first electrode structures includes: forming a storage recess in the memory array region; and forming the second electrode structures isolated from the first electrode structures in the storage recess.

In some implementations, forming the storage recess in the memory array region includes: forming a first mesh opening extending through a first one of the first layers in the memory array region; removing a first part of a first one of the first dielectric layers in the memory array region through the first mesh opening to form a first recess, where a remaining part of the first one of the first dielectric layers in the contact region is isolated by the isolation structure and remains intact; forming a second mesh opening extending through a second one of the first layers in the memory array region; and removing a part of a second one of the first dielectric layers in the memory array region through the second mesh opening to form a second recess, where a remaining part of the second one of the first dielectric layers in the contact region is isolated by the isolation structure and remains intact. The storage recess includes the first meshing opening, the first recess, the second meshing opening, and the second recess.

In some implementations, forming the second electrode structures isolated from the first electrode structures includes: forming a storage dielectric layer to cover the first electrode structures in the storage recess; and forming the second electrode structures in the storage recess by depositing conductive layers over the storage dielectric layer to fill the storage recess.

In some implementations, the method further includes: forming a second semiconductor structure; and bonding the second semiconductor structure with the first semiconductor structure. The second semiconductor structure includes a peripheral circuit coupled with the memory cell array.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a schematic view of a cross-section of a 3D memory device, according to some aspects of the present disclosure.

FIG. 1B illustrates a schematic circuit diagram of a memory device including peripheral circuits and an array of dynamic random-access memory (DRAM) cells, according to some aspects of the present disclosure.

FIG. 2A illustrates a side view of a cross section of a memory device, according to some examples of the present disclosure.

FIG. 2B illustrates a plan view of a cross section of a memory device, according to some examples of the present disclosure.

FIGS. 3A-3M illustrate a fabrication process for forming a memory device, according to some examples of the present disclosure.

FIG. 4A illustrates a side view of a cross section of a memory device, according to some aspects of the present disclosure.

FIG. 4B illustrates a plan view of a cross section of a memory device, according to some aspects of the present disclosure.

FIG. 4C illustrates an enlarged view of vertical capacitors, according to some aspects of the present disclosure.

FIG. 4D illustrates another side view of a cross section of a memory device, according to some aspects of the present disclosure.

FIGS. 4E-4G illustrate a partial plan view of cross sections of an isolation structure, according to some aspects of the present disclosure.

FIGS. 5A-5U illustrate a fabrication process for forming a memory device, according to some aspects of the present disclosure.

FIGS. 6A-6J illustrate a fabrication process for forming an isolation structure, according to some aspects of the present disclosure.

FIGS. 7A-7I illustrate another fabrication process for forming an isolation structure, according to some aspects of the present disclosure.

FIG. 8A illustrates a flowchart of a method for forming a 3D memory device, according to some aspects of the present disclosure.

FIG. 8B illustrates a flowchart of a method for forming a first semiconductor structure, according to some aspects of the present disclosure.

FIG. 9 illustrates a block diagram of an exemplary system having a 3D memory device, according to some aspects of the present disclosure.

FIG. 10A illustrates a diagram of an exemplary memory card having a 3D memory device, according to some aspects of the present disclosure.

FIG. 10B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features, as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

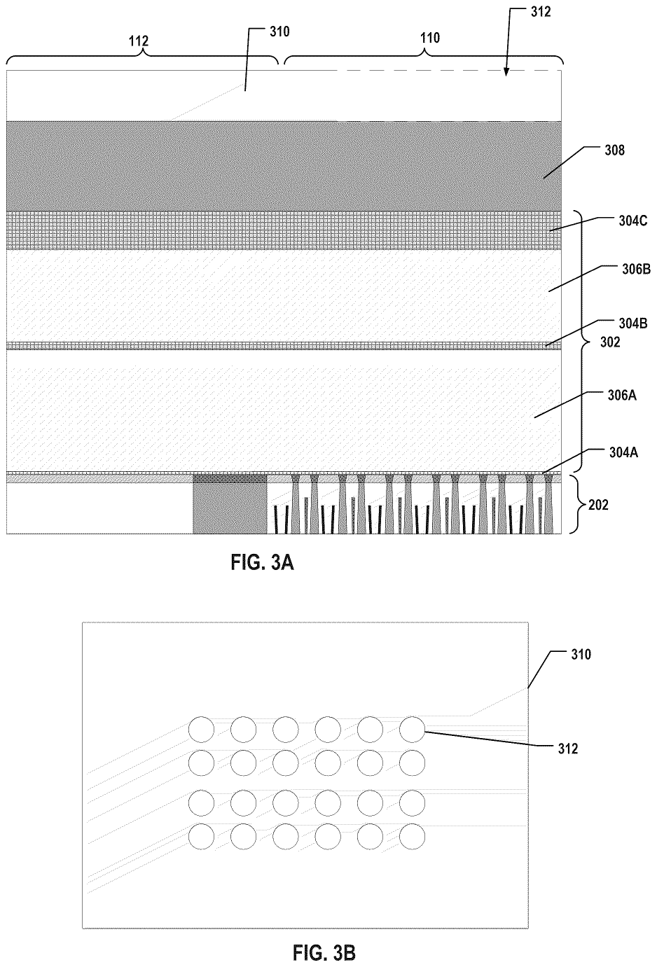

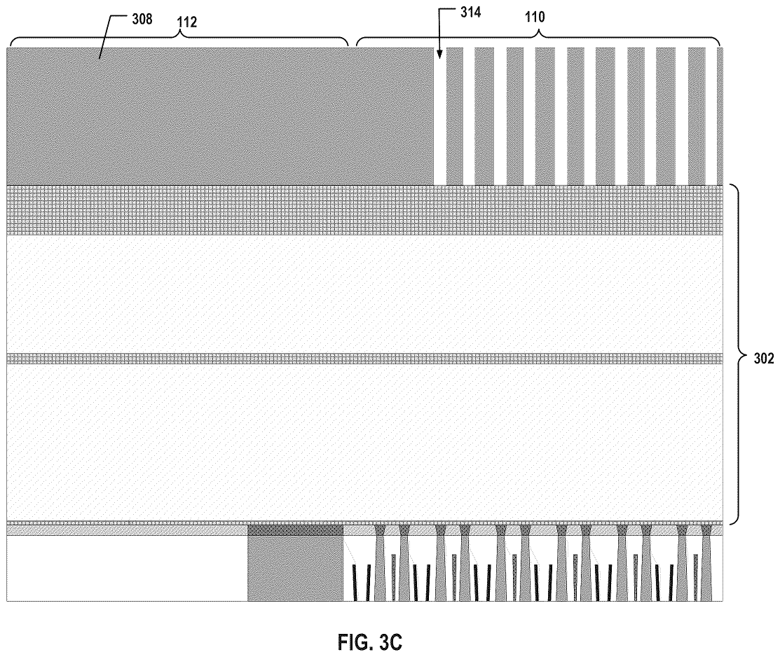

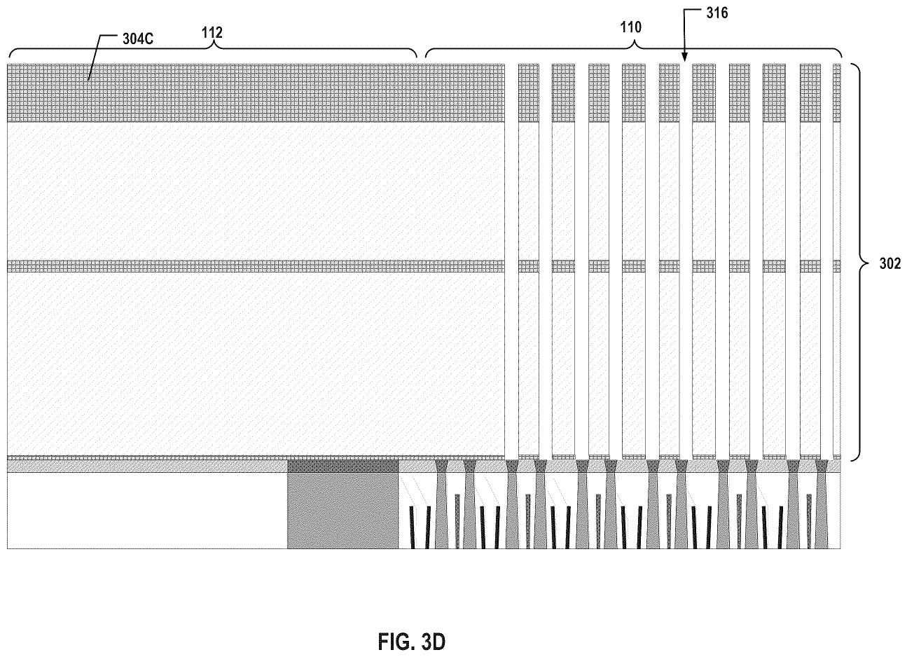

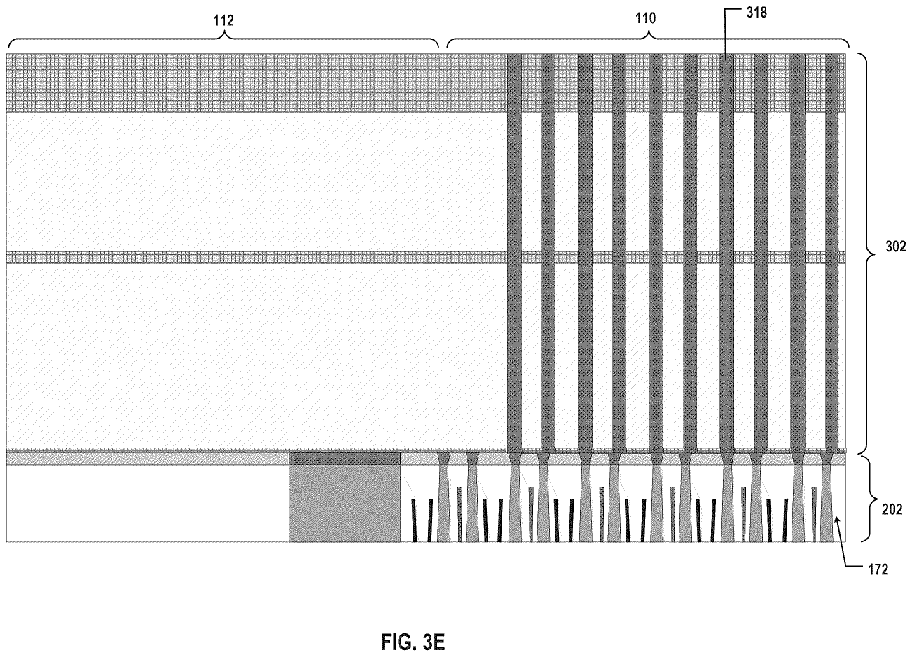

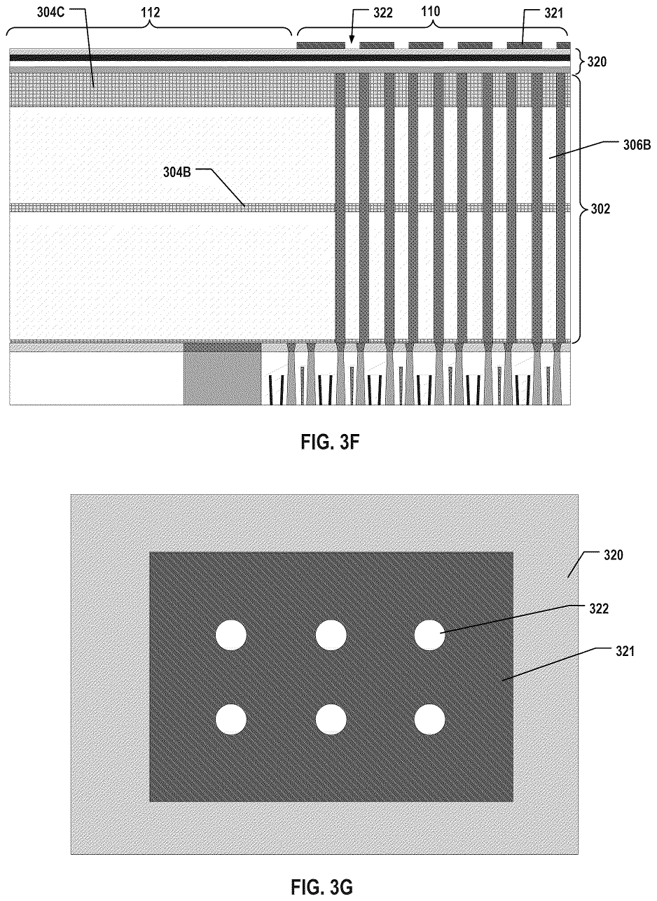

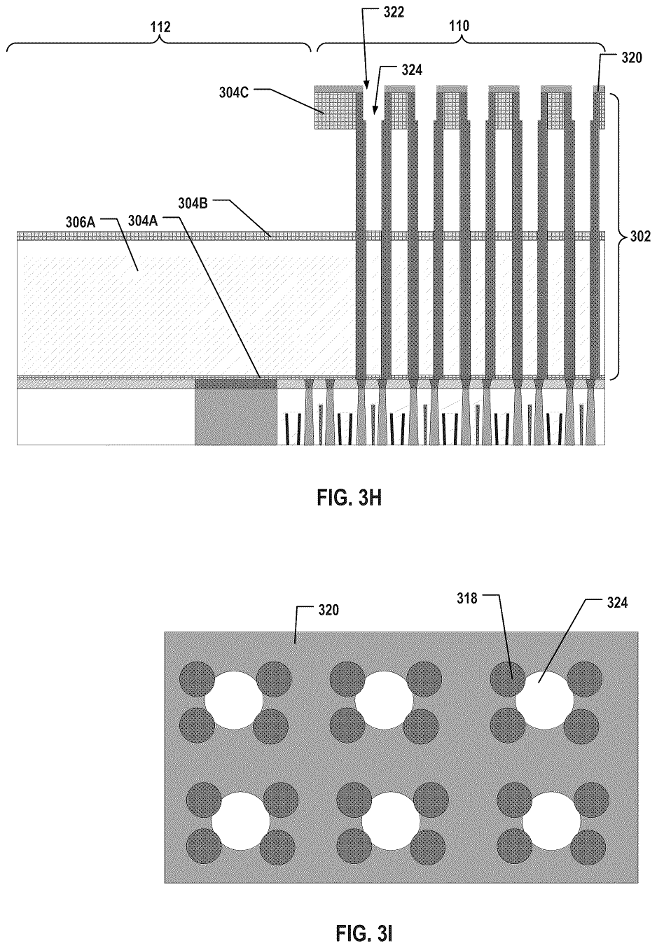

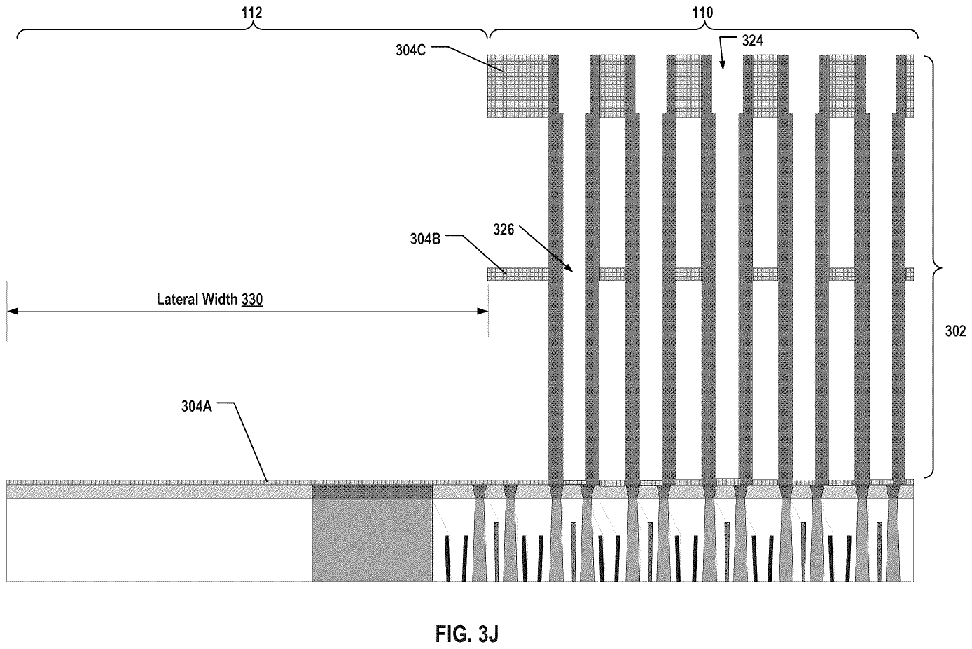

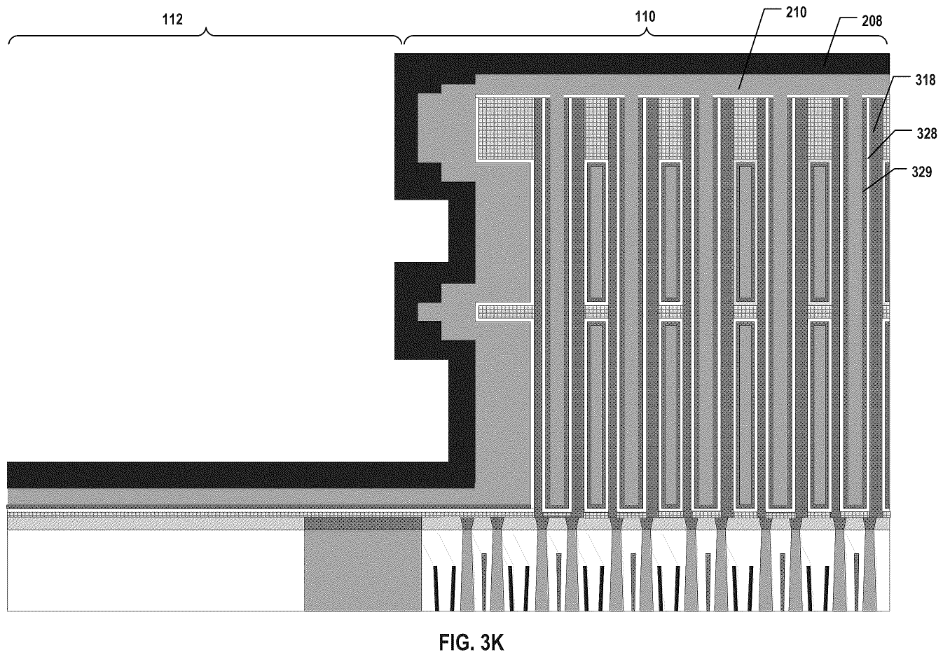

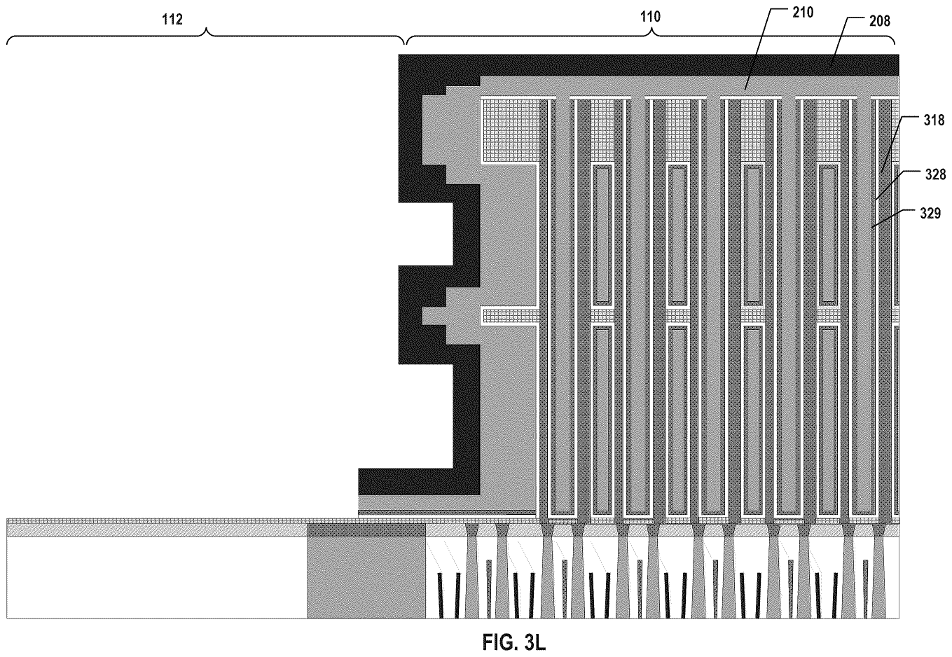

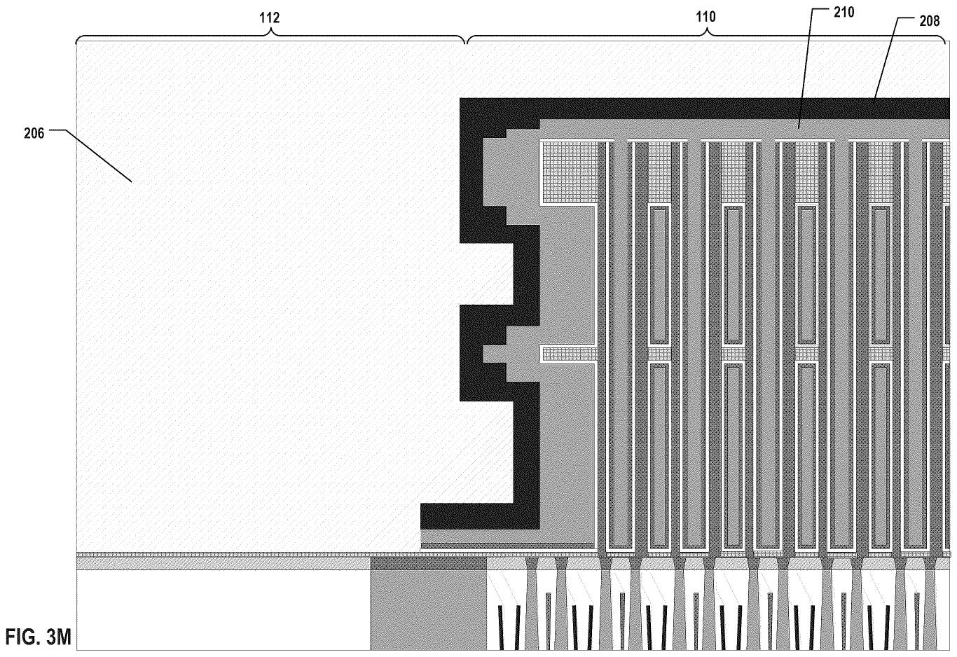

In some examples, a memory device may be divided into memory array regions and a contact region, where the memory array regions are separated from one another by the contact region (e.g., the memory array regions are surrounded by the contact region). Memory cell arrays may be formed in the respective memory array regions, and a dielectric material (e.g., a silicon oxide) may be filled in the contact region to isolate the memory cell arrays from one another. However, to fill the contact region with the dielectric material, a stack structure which is previously formed in the contact region needs to be removed (e.g., as shown in FIGS. 3H-3J below). This removal of the stack structure in the contact region and the refilling of the dielectric material in the contact region may result in a high manufacturing cost. Additionally, a lateral width (e.g., a lateral width 330 shown in FIG. 3J) for removing the stack structure in the contact region is large, which may result in a waste in the space between the memory cell arrays.

To address one or more of the aforementioned issues, the present disclosure introduces a solution in which an isolation structure may be formed between a memory array region and a contact region of a memory device. The isolation structure surrounds the memory array region to isolate the memory array region from the contact region. A memory cell array may be formed in the memory array region, whereas a stack structure remains intact in the contact region. That is, due to the existence of the isolation structure, the stack structure in the contact region does not need to be removed, and therefore, there is no need to refill the contact region with a dielectric material again to achieve the isolation of the memory cell array. As a result, the manufacturing cost can be reduced, and the space between memory cell arrays can be saved.

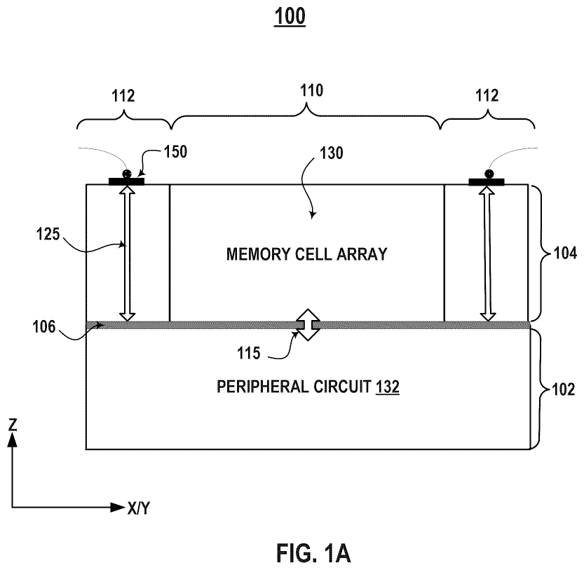

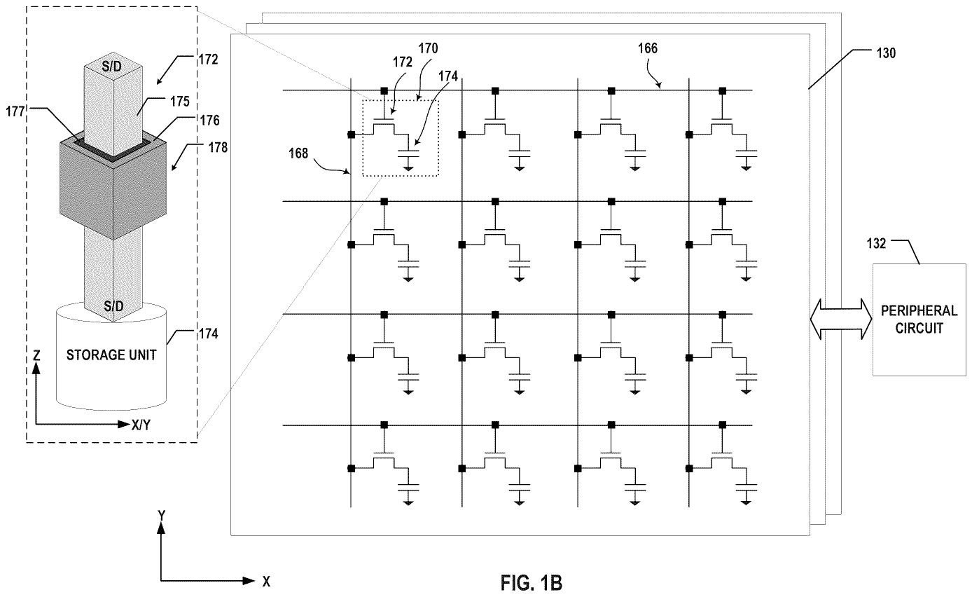

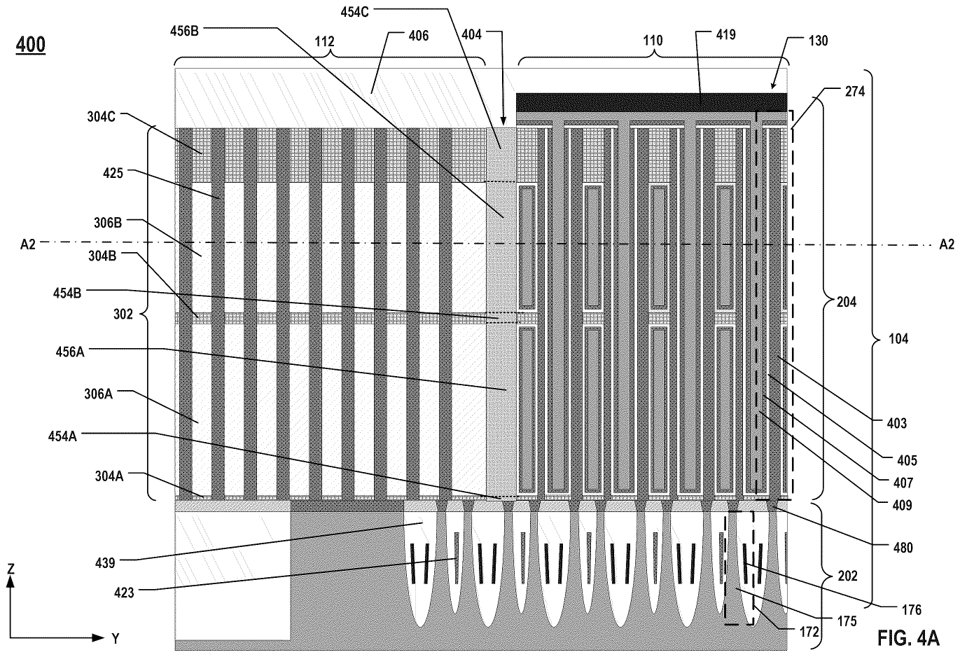

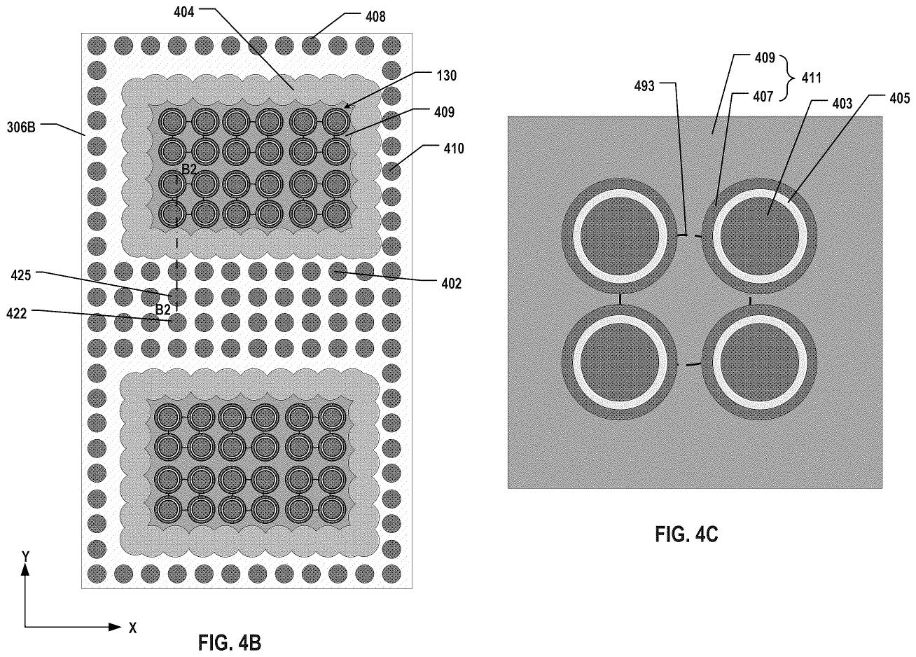

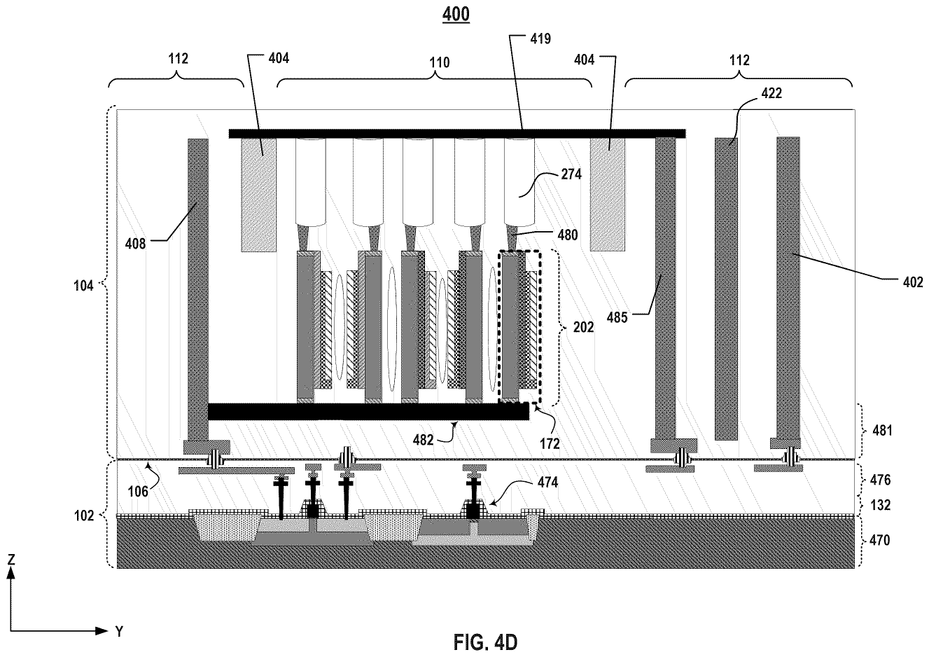

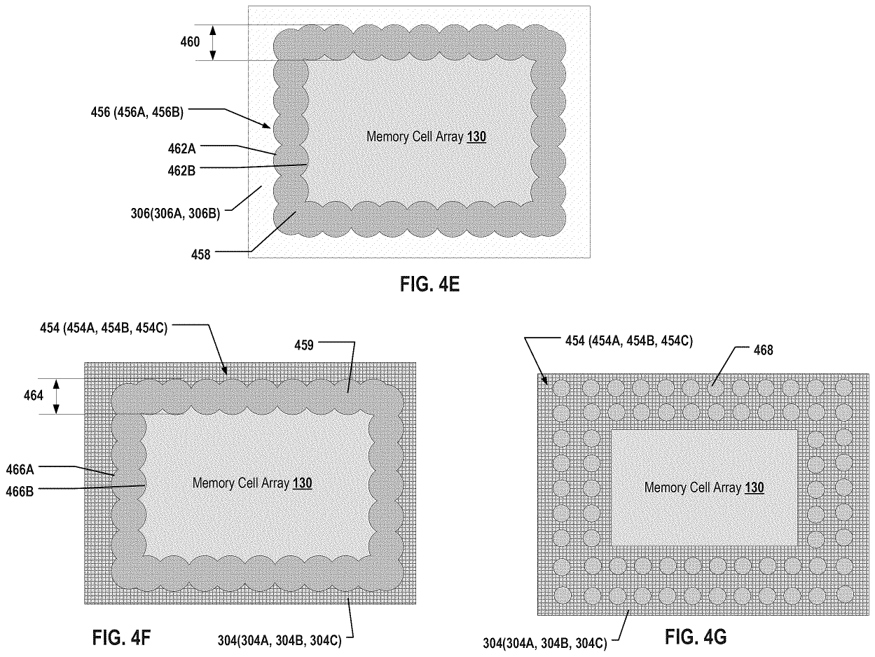

FIG. 1A illustrates a schematic view of a cross section of a 3D memory device 100, according to some aspects of the present disclosure. 3D memory device 100 represents an example of a bonded chip. The components of 3D memory device 100 (e.g., a memory cell array 130 and peripheral circuits 132) can be formed separately on different substrates and then jointed to form a bonded chip. 3D memory device 100 can include a first semiconductor structure 104 (also referred to as a memory structure) and a second semiconductor structure 102 (also referred to as a circuit structure). First semiconductor structure 104 may include (i) memory cell array 130 in a memory array region 110 and (ii) contact structures 125 (e.g., including contact structures 402, 408, 410, and 485 shown in FIGS. 4B and 4D) in a contact region 112. Second semiconductor structure 102 may include peripheral circuits 132 of memory cell array 130.

Peripheral circuits 132 (a.k.a. control and sensing circuits) can include any suitable digital, analog, and/or mixed-signal circuits used for facilitating the operations of memory cell array 130. For example, peripheral circuits 132 can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). Peripheral circuits 132 in second semiconductor structure 102 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

In some implementations, first semiconductor structure 104 can include an array of memory cells (memory cell array 130) that can use transistors as the switch and selecting devices. In some implementations, memory cell array 130 includes an array of DRAM cells. For ease of description, a DRAM cell array may be used as an example for describing memory cell array 130 in the present disclosure. But it is understood that memory cell array 130 is not limited to DRAM cell array and may include any other suitable types of memory cell arrays that can use transistors as the switch and selecting devices, such as phase-change memory (PCM) cell array, static random-access memory (SRAM) cell array, Ferroelectric Random Access Memory (FRAM) cell array, resistive memory cell array, magnetic memory cell array, spin transfer torque (STT) memory cell array, to name a few, or any combination thereof.

In some implementations, first semiconductor structure 104 can be a DRAM device in which memory cells are provided in the form of an array of DRAM cells. The DRAM cell includes a capacitor for storing a bit of data as a positive or negative electrical charge as well as one or more transistors (a.k.a. pass transistors) that control (e.g., switch and selecting) access to it. In some implementations, the DRAM cell is a one-transistor, one-capacitor (1T1C) cell. It is understood that the DRAM cell may be of any suitable configurations, such as 2T1C cell, 3T1C cell, etc. Since transistors always leak a small amount of charge, the capacitors will slowly discharge, causing information stored in them to drain. As such, a DRAM cell has to be refreshed to retain data, for example, by peripheral circuits 132 in second semiconductor structure 102, according to some implementations.

As shown in FIGS. 1A, 3D memory device 100 further includes a bonding interface 106 vertically between (in the vertical direction, e.g., the z-direction in FIG. 1A) second semiconductor structure 102 and first semiconductor structure 104. As described below in more detail, first semiconductor structure 104 and second semiconductor structure 102 can be fabricated separately (and in parallel in some implementations) such that the thermal budget of fabricating one of semiconductor structures 102 and 104 does not limit the processes of fabricating another one of semiconductor structures 102 and 104. Moreover, a large number of interconnects 115 (e.g., bonding contacts) can be formed through bonding interface 106 to make direct, short-distance (e.g., micron-level) electrical connections between second semiconductor structure 102 and first semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between memory cell array 130 in first semiconductor structure 104 and peripheral circuits 132 in second semiconductor structure 102 can be performed through interconnects 115 (e.g., bonding contacts) across bonding interface 106. By vertically integrating first and second semiconductor structures 104 and 102, the chip size can be reduced, and the memory cell density can be increased.

In some implementations as shown in FIG. 1A, contact structures 125 (e.g., a through silicon contact) can extend vertically in contact region 112. A first end of contact structure 125 can be electrically connected to a corresponding interconnect 115 or any other interconnect structure in first semiconductor structure 104. A second end of contact structure 125 can be electrically connected to a contact pad 150 through a pad-out interconnect layer (not shown). In some implementations, the pad-out interconnect layer and contact pad 150 can transfer electrical signals between 3D memory device 100 and outside circuits, e.g., for pad-out purposes.

It is understood that the relative positions of stacked first and second semiconductor structures 104 and 102 are not limited. Bonding interface 106 is formed vertically between first and second semiconductor structures 104 and 102 in 3D memory device 100, and first and second semiconductor structures 104 and 102 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between memory cell array 130 in first semiconductor structure 104 and peripheral circuits 132 in second semiconductor structure 102 can be performed through interconnects 115 (e.g., bonding contacts) across bonding interface 106.

It is noted that x, y, and z axes are included in FIG. 1A to further illustrate the spatial relationship of the components in 3D memory devices 100. The substrate of the 3D memory device includes two lateral surfaces extending laterally in the x-y plane: a top surface on the front side of the wafer on which the semiconductor devices can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the 3D memory device is determined relative to the substrate of the 3D memory device in the z-direction (the vertical direction perpendicular to the x-y plane, e.g., the thickness direction of the substrate) when the substrate is positioned in the lowest plane of the 3D memory device in the z-direction. The same notion for describing the spatial relationships is applied throughout the present disclosure.

FIG. 1B illustrates a schematic diagram of a memory device 160 including peripheral circuits 132 and memory cell array 130 (e.g., an array of memory cells 170), according to some aspects of the present disclosure. Peripheral circuits 132 are coupled to memory cell array 130. Memory device 160 can be an example of 3D memory device 100. Memory cell array 130 can be any suitable memory cell array in which memory cell 170 includes a vertical transistor 172 and a storage unit 174 coupled to vertical transistor 172. In some implementations, memory cell array 130 is a DRAM cell array, and storage unit 174 is a capacitor for storing charge as the binary information stored by the respective DRAM cell. In some implementations, memory cell array 130 is a PCM cell array, and storage unit 174 is a PCM element (e.g., including chalcogenide alloys) for storing binary information of the respective PCM cell based on the different resistivities of the PCM element in the amorphous phase and the crystalline phase. In some implementations, memory cell array 130 is a FRAM cell array, and storage unit 174 is a ferroelectric capacitor for storing binary information of the respective FRAM cell based on the switch between two polarization states of ferroelectric materials under an external electric field.

As shown in FIG. 1B, memory cells 170 can be arranged in a two-dimensional (2D) array having rows and columns. Memory device 160 can include word lines 166 coupling to peripheral circuits 132 and memory cell array 130 for controlling the switch of vertical transistors 172 in memory cells 170 located in a row, as well as bit lines 168 coupling to peripheral circuits 132 and memory cell array 130 for sending data to and/or receiving data from memory cells 170 located in a column. That is, word line 166 is coupled to a respective row of memory cells 170, and bit line 168 is coupled to a respective column of memory cells 170.

Consistent with the scope of the present disclosure, vertical transistors 172, such as vertical metal-oxide-semiconductor field-effect transistors (MOSFETs), can replace the conventional planar transistors as the pass transistors of memory cells 170 to reduce the area occupied by the pass transistors, the coupling capacitance, as well as the interconnect routing complexity. As shown in FIG. 1B, in some implementations, different from planar transistors in which the active regions are formed in the substrates, vertical transistor 172 includes a semiconductor body 175 extending vertically (in the z-direction) above the substrate (not shown). That is, semiconductor body 175 can extend above the top surface of the substrate to expose not only the top surface of semiconductor body 175, but also one or more side surfaces thereof. As shown in FIG. 1A, for example, semiconductor body 175 can have a cuboid shape to expose four sides thereof. It is understood that semiconductor body 175 may have any suitable 3D shape, such as a polyhedron shape or a cylinder shape. That is, the cross section of semiconductor body 175 in the plan view (e.g., in the x-y plane) can have a square shape, a rectangular shape (or a trapezoidal shape), a circular (or an oval shape), or any other suitable shapes. It is understood that consistent with the scope of the present disclosure, for semiconductor bodies that have a circular or oval shape of their cross-sections in the plan view, the semiconductor bodies may still be considered to have multiple sides, such that the gate structures are in contact with more than one side of the semiconductor bodies. Semiconductor body 175 can be formed from the substrate (e.g., by etching or epitaxy) and thus, has the same semiconductor material (e.g., crystalline silicon) as the substrate (e.g., a silicon substrate).

In some implementations, vertical transistor 172 can also include a gate structure 178 in contact with one or more sides of semiconductor body 175, i.e., in one or more planes of the side surface(s) of the active region. In other words, the active region of vertical transistor 172, i.e., semiconductor body 175, can be at least partially surrounded by gate structure 178. It is noted that, FIG. 1B shows that gate structure 178 can be an all-around-gate structure laterally surrounding all sides of semiconductor body 175. In some other implementations not shown in FIG. 1B, gate structure 178 can include one or more flat sides or curved sides partially surrounding semiconductor body 175.

Gate structure 178 can include a gate dielectric layer 177 over one or more sides of semiconductor body 175, e.g., in contact with four side surfaces of semiconductor body 175, as shown in FIG. 1B. Gate structure 178 can also include a gate electrode 176 over and in contact with gate dielectric layer 177. Gate dielectric layer 177 can include any suitable dielectric materials, such as silicon oxide, silicon nitride, silicon oxynitride, or high-k dielectrics. For example, gate dielectric layer 177 may include silicon oxide, i.e., gate oxide. Gate electrode 176 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 176 may include doped polysilicon, i.e., a gate poly. In some implementations, gate electrode 176 includes multiple conductive layers, such as a W layer over a TiN layer. It is understood that gate electrode 176 and word line 166 may be a continuous conductive structure in some examples. In other words, gate electrode 176 may be viewed as part of word line 166 that forms gate structure 178, or word line 166 may be viewed as the extension of gate electrode 176 to be coupled to peripheral circuits 132.

As shown in FIG. 1B, vertical transistor 172 can further include a pair of a source and a drain (S/D, doped regions, a.k.a., source electrode and drain electrode) formed at the two ends of semiconductor body 175 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 178 in the vertical direction (the z-direction). In other words, gate structure 178 is formed vertically between the source and drain. As a result, one or more channels (not shown) of vertical transistor 172 can be formed in semiconductor body 175 vertically between the source and drain when a gate voltage applied to gate electrode 176 of gate structure 178 is above the threshold voltage of vertical transistor 172. That is, the channel of vertical transistor 172 is also formed in the vertical direction along which semiconductor body 175 extends, according to some implementations.

In some implementations, as shown in FIG. 1B, vertical transistor 172 is a multi-gate transistor. That is, gate structure 178 can be in contact with more than one side of semiconductor body 175 (e.g., four sides in FIG. 1B) to form more than one gate, such that more than one channel can be formed between the source and drain in operation. It is understood that vertical transistors 172 disclosed herein may also include single-gate transistors. That is, gate structure 178 may be in contact with a single side of semiconductor body 175, for example, for the purpose of increasing the transistor and memory cell density. It is also understood that although gate dielectric layer 177 is shown as being separate (i.e., a separate structure) from other gate dielectrics of adjacent vertical transistors (not shown), gate dielectric layer 177 may be part of a continuous dielectric layer having multiple gate dielectric layers of vertical transistors 172.

In vertical transistor 172, semiconductor body 175 extends vertically (in the z-direction), and the source and the drain are disposed in the different lateral planes, according to some implementations. In some implementations, the source and the drain are formed at two ends of semiconductor body 175 in the vertical direction (the z-direction), respectively, thereby overlapping in the plan view. As a result, the area (in the x-y plane) occupied by vertical transistor 172 can be reduced compared with planar transistors and lateral multiple-gate transistors. Also, the metal wiring coupled to vertical transistors 172 can be simplified as well since the interconnects can be routed in different planes. For example, bit lines 168 and storage units 174 may be formed on opposite sides of vertical transistor 172. In one example, bit line 168 may be coupled to the source or the drain at the upper end of semiconductor body 175, while storage unit 174 may be coupled to the other source or the drain at the lower end of semiconductor body 175.

As shown in FIG. 1B, storage unit 174 can be coupled to the source or the drain of vertical transistor 172. Storage units 174 can include any devices that are capable of storing binary data (e.g., 0 and 1), including but not limited to, capacitors for DRAM cells and FRAM cells, and PCM elements for PCM cells. In some implementations, vertical transistor 172 controls the selection and/or the state switch of the respective storage unit 174 coupled to vertical transistor 172. In some implementations as shown in FIG. 1B, memory cell 170 is a DRAM cell including vertical transistor 172 and a capacitor (e.g., an example of storage unit 174 in FIG. 1B). In some implementations, the capacitor is a vertical compactor. An example structure of the vertical capacitor is described below in more detail with reference to FIGS. 4A-4C.

Peripheral circuits 132 can be coupled to memory cell array 130 through bit lines 168, word lines 166, and any other suitable metal wirings. As described above, peripheral circuits 132 can include any suitable circuits for facilitating the operations of memory cell array 130 by applying and sensing voltage signals and/or current signals through word lines 166 and bit lines 168 to and from memory cell 170.

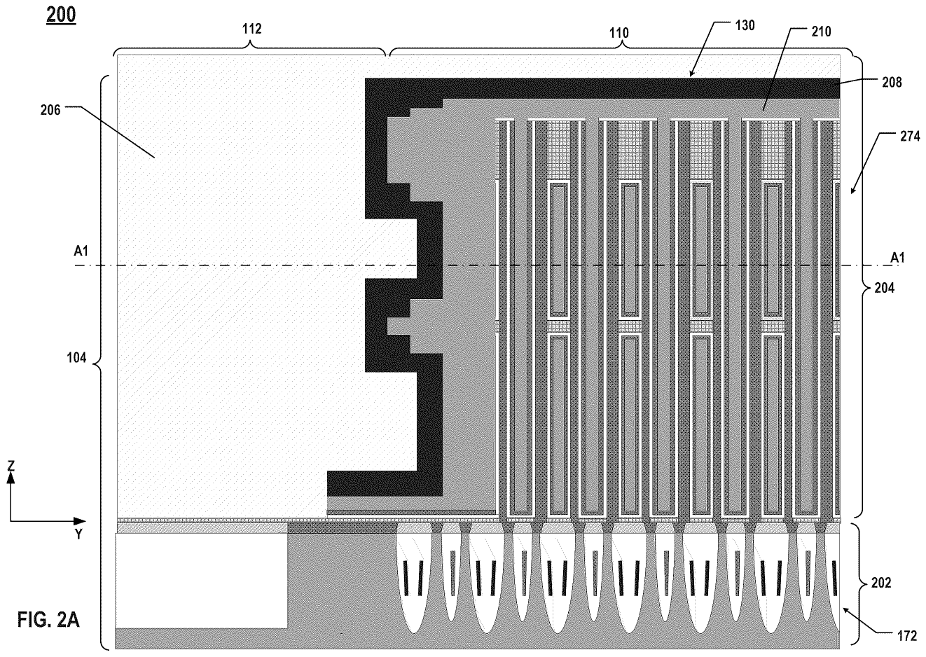

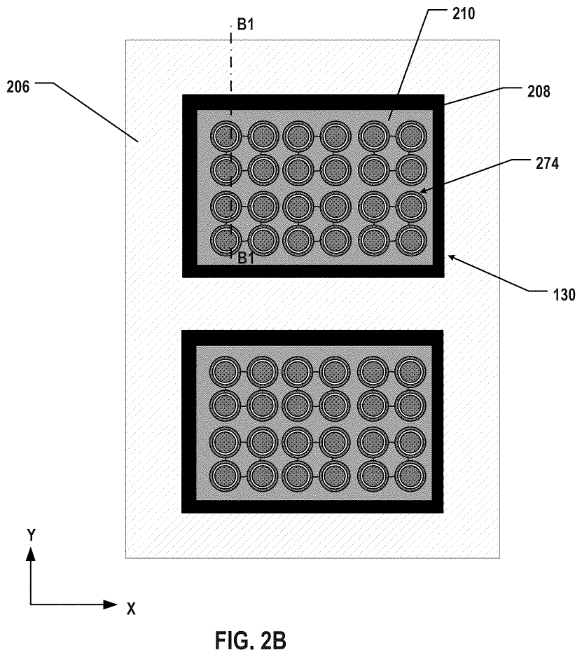

FIG. 2A illustrates a side view of a cross section of a memory device 200, according to some examples of the present disclosure. FIG. 2B illustrates a plan view of a cross section of memory device 200, according to some examples of the present disclosure. The cross section of memory device 200 in FIG. 2B is along a line A1-A1 in FIG. 2A. The cross section of memory device 200 in FIG. 2A is along a line B1-B1 in FIG. 2B. FIGS. 2A and 2B are described together.

Memory device 200 may be an example of 3D memory device 100 of FIG. 1A. As shown in FIG. 2A, memory device 200 may include first semiconductor structure 104. First semiconductor structure 104 includes a transistor structure 202 and a storage structure 204 stacked over transistor structure 202. Transistor structure 202 may include an array of transistors (e.g., an array of vertical transistors 172). Storage structure 204 may include an array of vertical capacitors 274 in memory array region 110. The array of vertical capacitors 274 may include a GeSi layer 210. A W layer 208 may cover GeSi layer 210. Storage structure 204 may further include a dielectric structure 206, which is formed by filling contact region 112 with a dielectric material (e.g., silicon oxide). A part of dielectric structure 206 may be formed on top of W layer 208 to cover W layer 208. As shown in FIG. 2B, memory cell arrays 130 in memory device 200 are separated and isolated by dielectric structure 206.

FIGS. 3A-3M illustrate a fabrication process for forming memory device 200, according to some examples of the present disclosure. Referring to FIGS. 3A and 3B (e.g., FIG. 3B is a plan view of the structure of FIG. 3A), transistor structure 202 including an array of vertical transistors 172 is formed. A stack structure 302 is formed on transistor structure 202. Stack structure 302 may be formed by depositing alternating first layers 304 (304A, 304B, 304C) and first dielectric layers 306 (306A, 306B) on transistor structure 202 across memory array region 110 and contact region 112, using one or more thin film deposition processes including, but not limited to, chemical vapor deposition (CVD), physical vapor deposition (PVD), atomic layer deposition (ALD), or any combination thereof. First dielectric layers 306 may include the same dielectric material, whereas first layers 304 may include the same dielectric material or different dielectric materials. The dielectric material(s) of first layers 304 may be different from the dielectric material of first dielectric layers 306. For example, first dielectric layers 306A and 306B may include silicon oxide. First layer 304A may include silicon nitride (SiN) or silicon boron nitride (SiBN). First layer 304B may include silicon carbon nitride (SiCN). First layer 304C may include SiN or SiCN.

Hard masks 308 and 310 may be formed on top of stack structure 302. Hard mask 308 may include polysilicon, whereas hard mask 310 may include silicon oxide. Hard mask 310 may be etched to form openings 312 in memory array region 110. In some implementations, fabrication processes for forming openings 312 include wet etching and/or dry etching, such as deep-ion reactive etching (DRIE).

Referring to FIG. 3C, hard mask 308 may be etched to form openings 314 through openings 312 of hard mask 310 of FIG. 3A in memory array region 110. In some implementations, fabrication processes for forming openings 314 include wet etching and/or dry etching, such as DRIE. Then, hard mask 310 of FIG. 3A, which covers hard mask 308 may be removed.

Referring to FIG. 3D, stack structure 302 may be etched from storage openings 316, which extend through stack structure 302 in memory array region 110. In some implementations, fabrication processes for forming storage openings 316 include wet etching and/or dry etching, such as DRIE. Then, hard mask 308 of FIG. 3C which covers stack structure 302 may be removed.

Referring to FIG. 3E, first electrode structures 318 of vertical capacitors 274 are formed in storage openings 316 of FIG. 3D. First electrode structures 318 may be formed by depositing one or more conductive layers into storage openings 316 using one or more thin film deposition processes such as CVD, PVD, ALD, or any combination thereof. For example, first electrode structures 318 may be formed by filling storage openings 316 with titanium nitride (TiN). First electrode structure 318 may be coupled to a respective vertical transistor 172 in transistor structure 202.

Referring to FIGS. 3F and 3G (e.g., FIG. 3G is a plan view of the structure of FIG. 3F), a mesh hard mask 320 can be deposited on top of stack structure 302 of FIG. 3E. A photoresist layer 321 can be deposited on top of mesh hard mask 320. Photoresist layer 321 may be patterned to form openings 322 to expose mesh hard mask 320 through openings 322 in memory array region 110. A part of photoresist layer 321 in contact region 112 may also be removed to expose mesh hard mask 320 in contact region 112. Portions of mesh hard mask 320 exposed by photoresist layer 321 may be etched to expose first layer 304C, such that the exposed portions of first layer 304C can be etched away as shown in FIG. 3H below.

Referring to FIGS. 3H and 3I (e.g., FIG. 3I is a plan view of the structure of FIG. 3H), first layer 304C may be etched to form mesh openings 324 in memory array region 110 through openings 322 in mesh hard mask 320 of FIG. 3F. The part of mesh hard mask 320 in contact region 112 and the part of first layer 304C in contact region 112 are completely removed. Then, the entire first dielectric layer 306B between first layer 304C and first layer 304B (shown in FIG. 3F) is removed using wet etching and/or dry etching, such as DRIE.

Referring to FIG. 3J, first layer 304B may be etched to form mesh openings 326 in memory array region 110 through openings 322 in mesh hard mask 320 and mesh openings 324. The part of first layer 304B in contact region 112 is completely removed. Then, the entire first dielectric layer 306A between first layer 304B and first layer 304A (shown in FIG. 3H) is removed using wet etching and/or dry etching, such as DRIE.

Referring to FIG. 3K, second electrode structures corresponding to vertical capacitors 274 may be formed in memory array region 110 by depositing a high dielectric constant (high-k) dielectric layer 328 to cover first electrode structures 318 and depositing one or more conductive layers over the high-k dielectric layer (e.g., depositing a TiN layer 329 and GeSi layer 210 over high-k dielectric layer 328, and then depositing W layer 208 over GeSi layer 210). High-k dielectric layer 328, TiN layer 329, GeSi layer 210, and W layer 208 may also extend across contact region 112 and memory array region 110.

Referring to FIG. 3L, a part of high-k dielectric layer 328, a part of TiN layer 329, a part of GeSi layer 210, and a part of W layer 208 in contact region 112 may be etched away. Referring to FIG. 3M, dielectric structure 206 may be formed by filling contact region 112 with a dielectric material (e.g., silicon oxide). Dielectric structure 206 may also cover W layer 208 in memory array region 110 as shown in FIG. 3M.

As shown in FIGS. 3H-3J above, to form dielectric structure 206, a part of stack structure 302 in contact region 112 needs to be completely removed. This removal of stack structure 302 in contact region 112, as well as the refilling of a dielectric material in contact region 112 to form dielectric structure 206, may result in a high manufacturing cost. Additionally, lateral width 330 (shown in FIG. 3J) for removing stack structure 302 in contact region 112 is large, which may result in waste in the space between the memory cell arrays.

FIG. 4A illustrates a side view of a cross section of a memory device 400, according to some aspects of the present disclosure. FIG. 4B illustrates a plan view of a cross section of memory device 400, according to some aspects of the present disclosure. The cross section of FIG. 4A is along a line B2-B2 of FIG. 4B, whereas the cross section of FIG. 4B is along a line A2-A2 of FIG. 4A. FIGS. 4A and 4B are described together. It is understood that FIGS. 4A and 4B are for illustrative purposes only and may not necessarily reflect the actual device structure (e.g., interconnections) in practice.

Memory device 400 can be a DRAM memory device including an array of DRAM cells. As shown in FIG. 4A, memory device 400 can include first semiconductor structure 104, which includes transistor structure 202 and storage structure 204. In some implementations, transistor structure 202 includes an array of vertical transistors 172, and storage structure 204 includes an array of vertical capacitors 274 in memory array region 110. That is, the DRAM cell can include a vertical capacitor 274 and a vertical transistor 172 coupled with vertical capacitor 274. In some implementations, an array of source node contact (SNC) structures 480 are coupled between the array of vertical transistors 172 and the array of vertical capacitors 274. In some examples, the array of vertical transistors 172 and the array of vertical capacitors 274 may form a memory cell array 130 in memory array region 110.

In some implementations, vertical transistor 172 (e.g., a MOSFET) may be configured to switch a respective DRAM cell. Vertical transistor 172 includes semiconductor body 175 (i.e., the active region in which multiple channels can form) extending vertically (in the z-direction), and a gate structure located at one or more lateral sides of semiconductor body 175. In some implementations, semiconductor body 175 can include any suitable semiconductor material, such as monocrystalline silicon, polycrystalline silicon, or silicon-germanium. In some other implementations, the leakage value of the semiconductor body 175 is lower than a pico-ampere. For example, semiconductor body 175 can include a metal oxide semiconductor material, such as InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc. In some implementations, adjacent semiconductor bodies 175 can be laterally separated from each other by an isolation member 423 including isolation oxides (TISO) and/or air gaps.

In some implementations, semiconductor body 175 extends in a vertical direction (the z-direction), and includes a source and a drain disposed at the two ends (the upper end and lower end) of semiconductor body 175, respectively. Source and drain can be doped with N-type dopants (e.g., P or As) or P-type dopants (e.g., B or Ga) at a desired doping level. In some implementations, the source is coupled to vertical capacitor 274 through SNC structure 480, and the drain is coupled to a bit line (not shown). In some implementations, the sources of adjacent semiconductor bodies 175 can be laterally separated from each other by an insulating layer 439 including any suitable dielectric material (e.g., silicon oxide). In some implementations, the drains of semiconductor bodies 175 of a column of DRAM cells along the bit line direction (i.e., the y-direction) can be laterally connected with each other to form a common drain that is coupled to a common bit line (not shown), which extends in the bit line direction (the y-direction).

In some implementations, the gate structure of vertical transistor 172 includes a gate dielectric layer and a gate electrode 176. In some implementations, the gate dielectric layer includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 176 includes conductive materials including, but not limited to, W, Co, Cu, Al, TiN, TaN, polysilicon, silicide, or any combination thereof. In some implementations, gate electrode 176 includes multiple conductive layers, such as a W layer over a TiN layer. In one example, the gate structure may be a “gate oxide/gate poly” gate in which the gate dielectric layer includes silicon oxide, and the gate electrode 176 includes doped polysilicon. In another example, the gate structure may be a high-k metal gate (HKMG) in which the gate dielectric layer includes a high-k dielectric, and the gate electrode 176 includes a metal. In some implementations, the gate structures of adjacent semiconductor bodies 175 can be laterally separated from each other by insulating layer 439.

In some implementations, gate electrode 176 may be part of a word line or extend in the word line direction (the x-direction) as a word line. The word line can extend in the word line direction (the x-direction), and be coupled to a row of DRAM cells. That is, the bit line and the word line can extend in two perpendicular lateral directions, and semiconductor body 175 of vertical transistor 172 can extend in the vertical direction perpendicular to the two lateral directions in which the bit line and the word line extend.

In some implementations, SNC structure 480 may include a conductive layer in contact with a corresponding vertical capacitor 274. In some implementations, the conductive layer can include any suitable conductive materials, such as polysilicon, Al, Cu, W, etc.

Vertical capacitor 274 can include a first electrode structure 403, a second electrode structure 411 (shown in FIG. 4C), and a storage dielectric layer 405 formed between first electrode structure 403 and second electrode structure 411. Referring to FIG. 4A, first electrode structure 403 can have a cylinder shape fixed in first layers 304A, 304B, and 304C. First and second electrode structures 403 and 411, as well as storage dielectric layer 405, extend vertically (in the z-direction), and storage dielectric layer 405 can be sandwiched between first and second electrode structures 403 and 411. In some implementations, second electrode structures 411 are connected with each other and function as a common electrode, while first electrode structure 403 is coupled to a source of a respective vertical transistor 172 in the same DRAM cell through SNC structure 480.

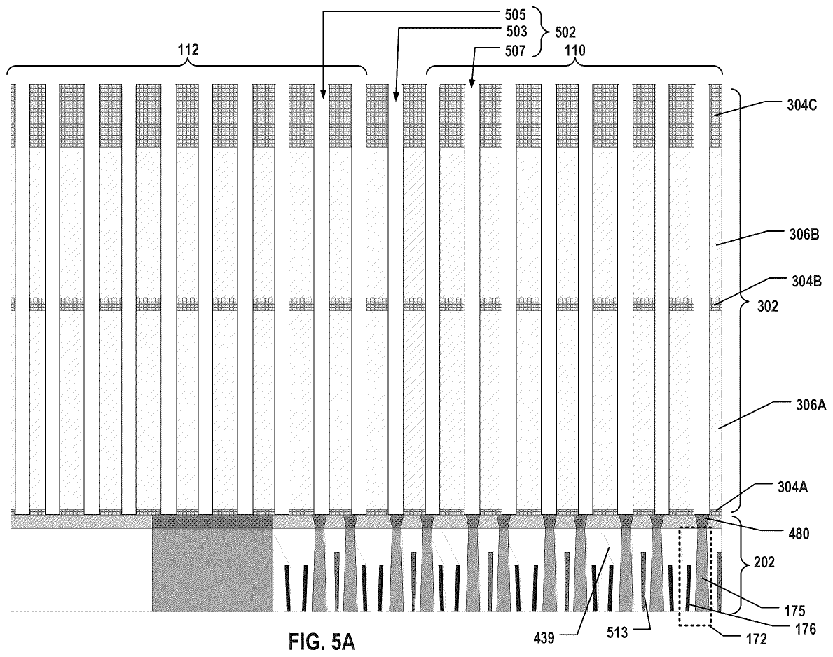

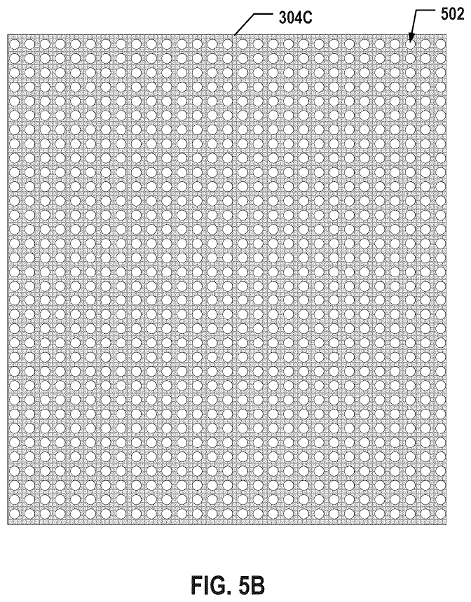

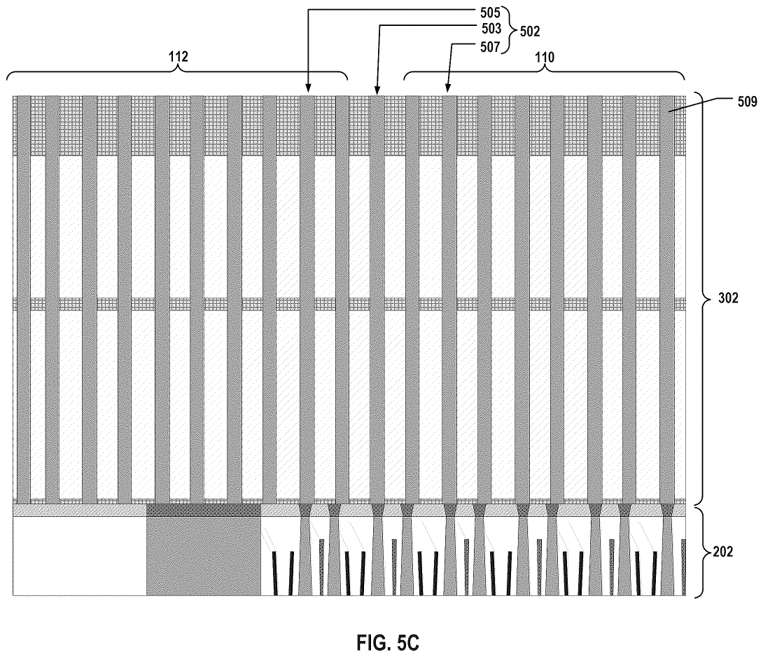

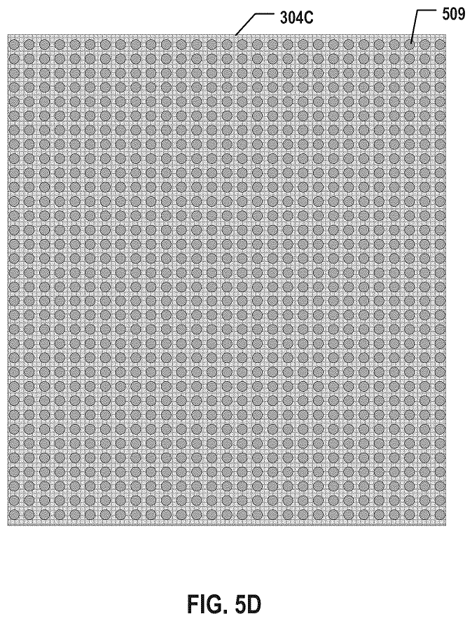

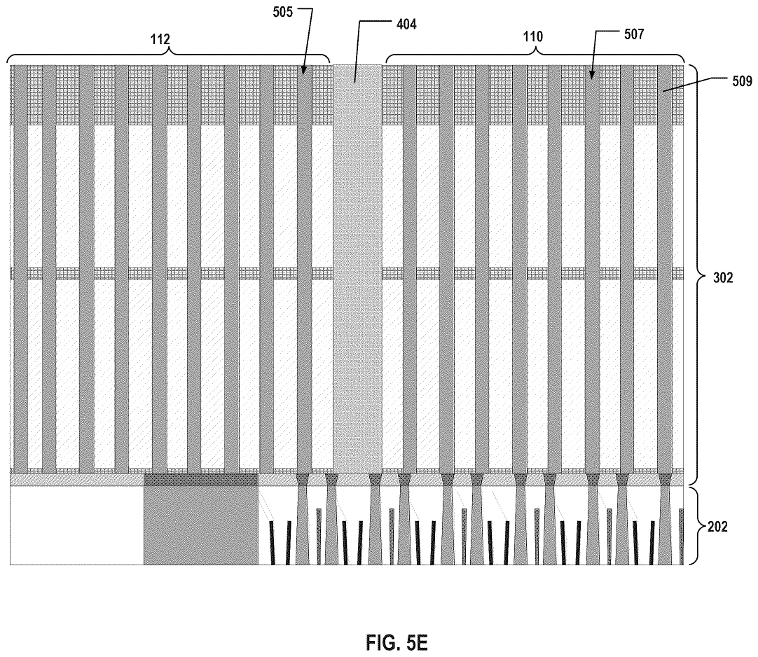

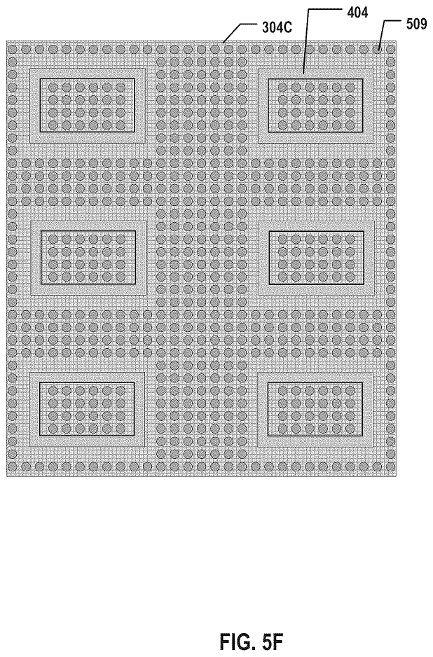

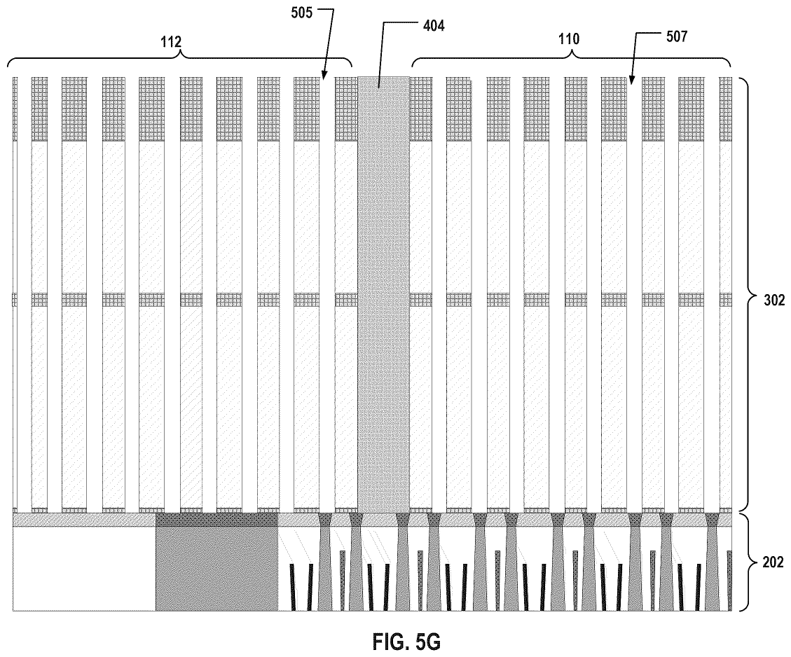

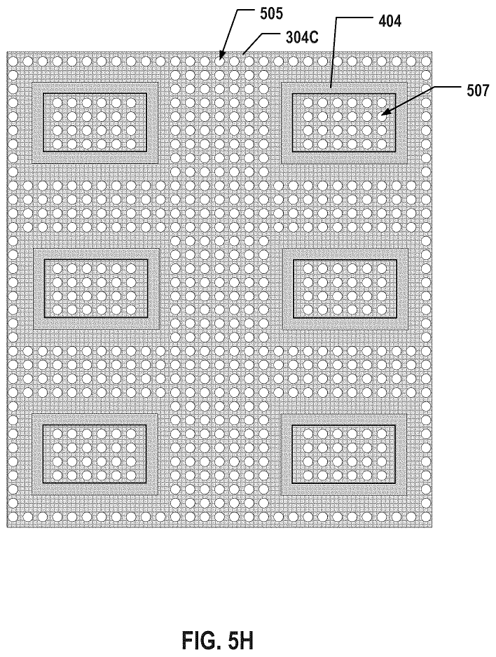

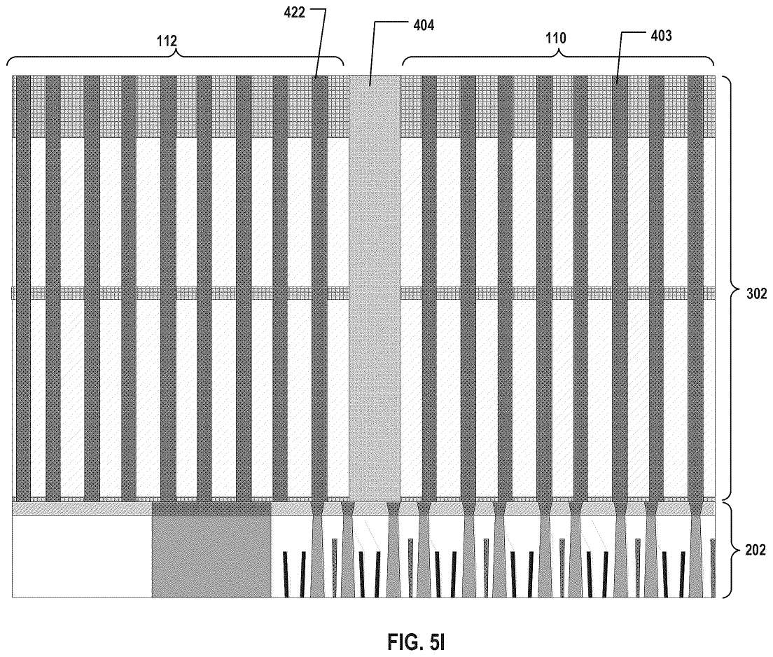

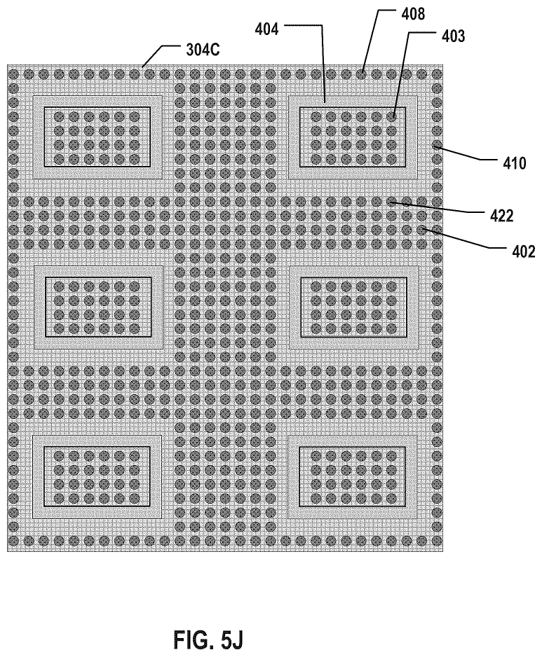

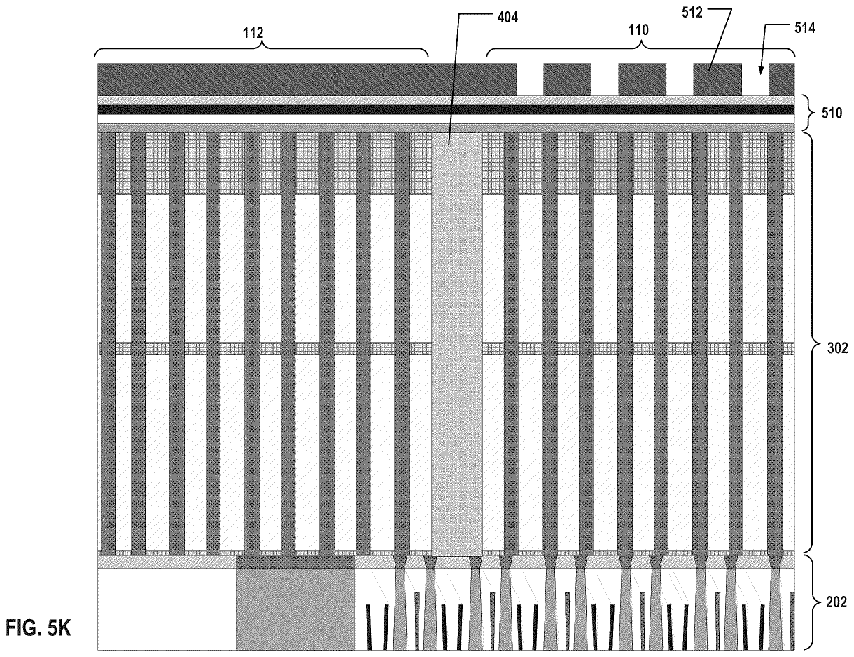

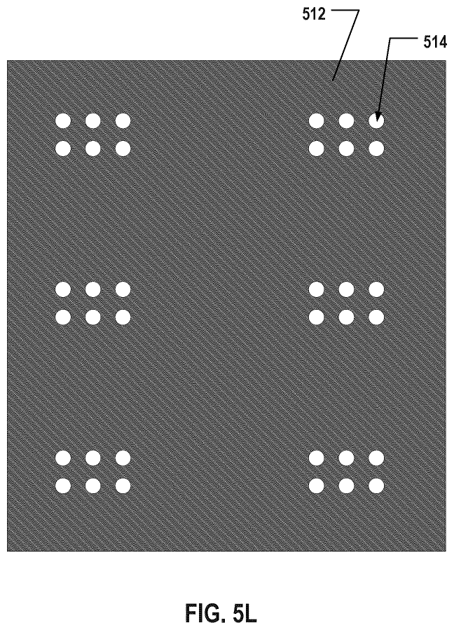

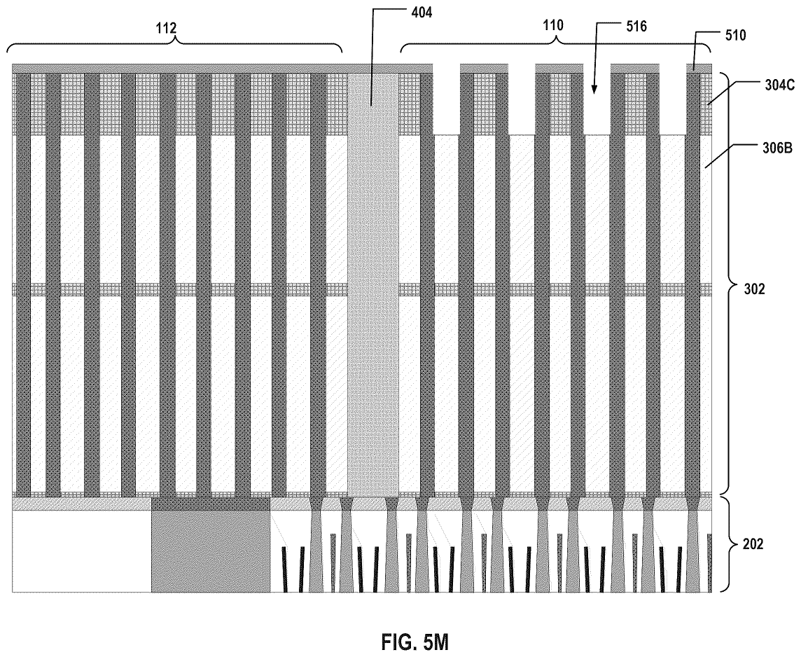

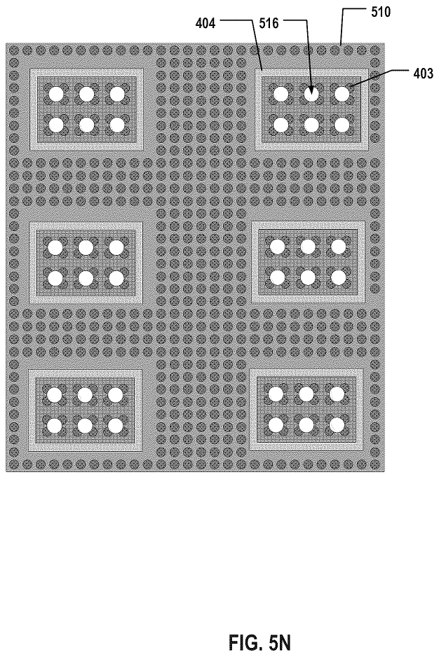

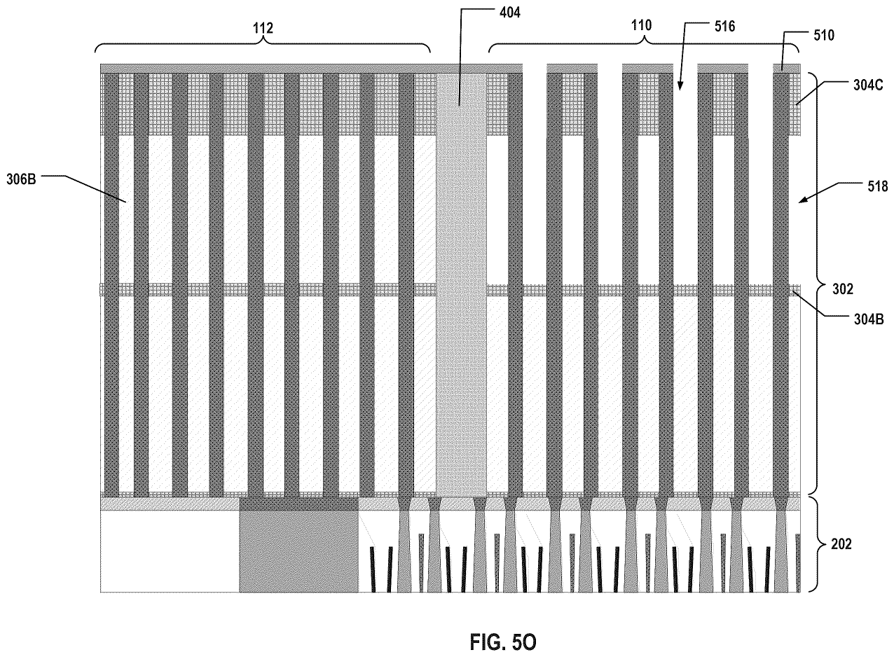

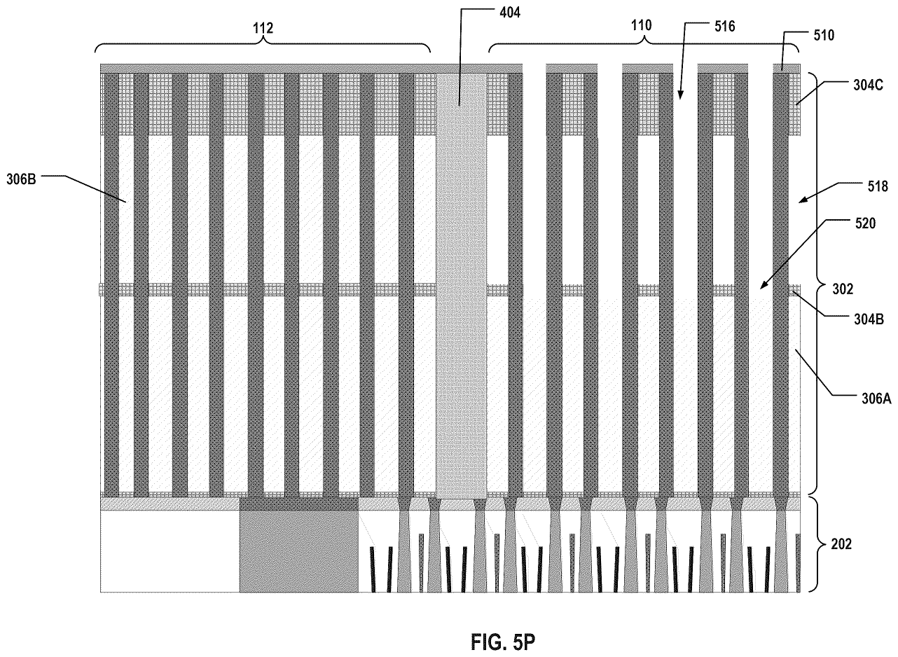

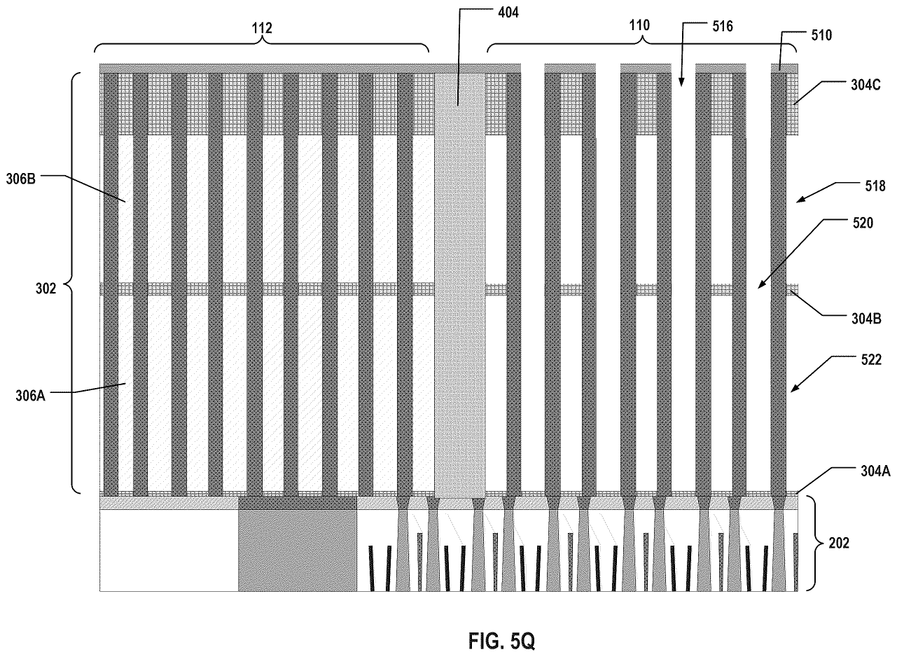

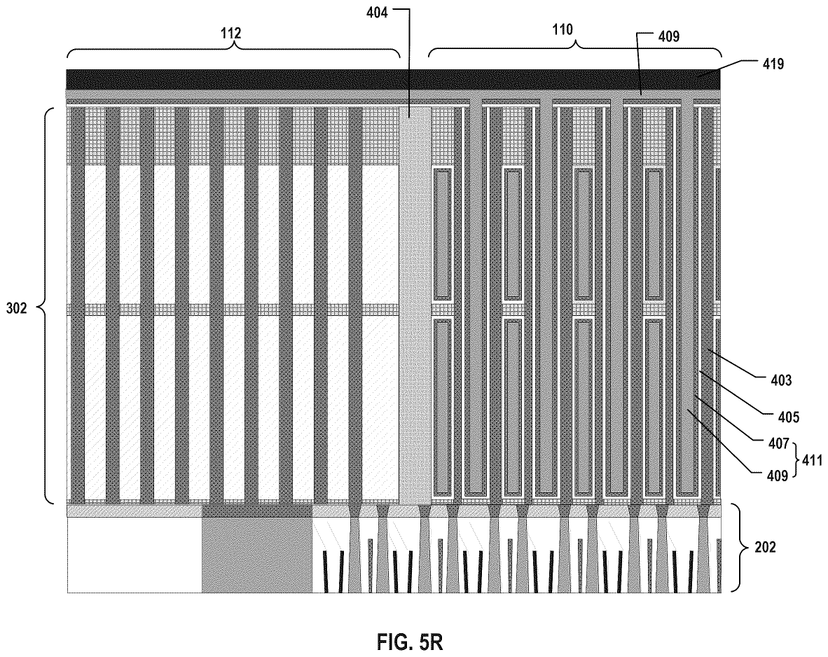

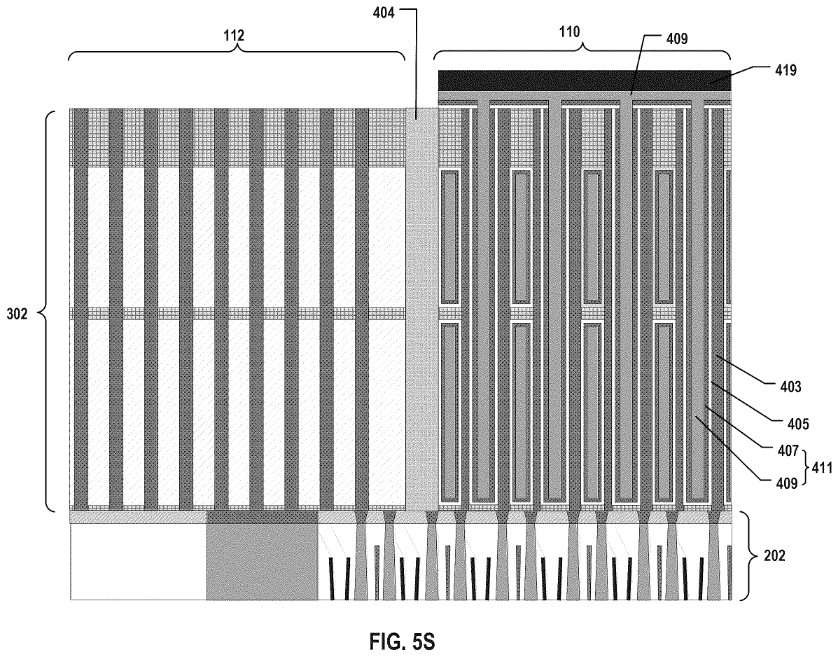

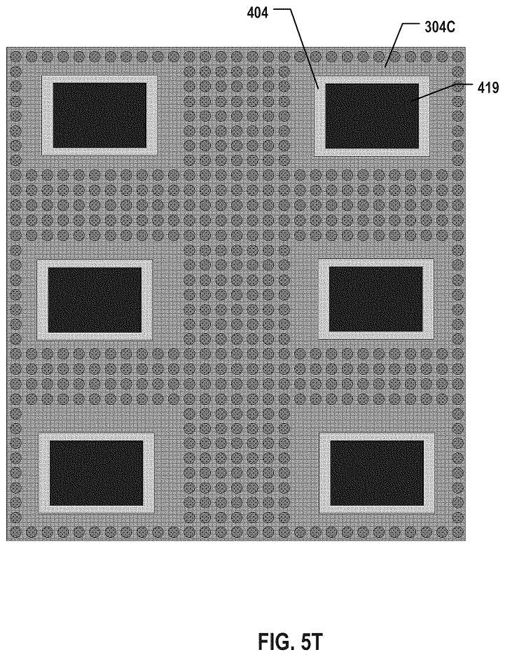

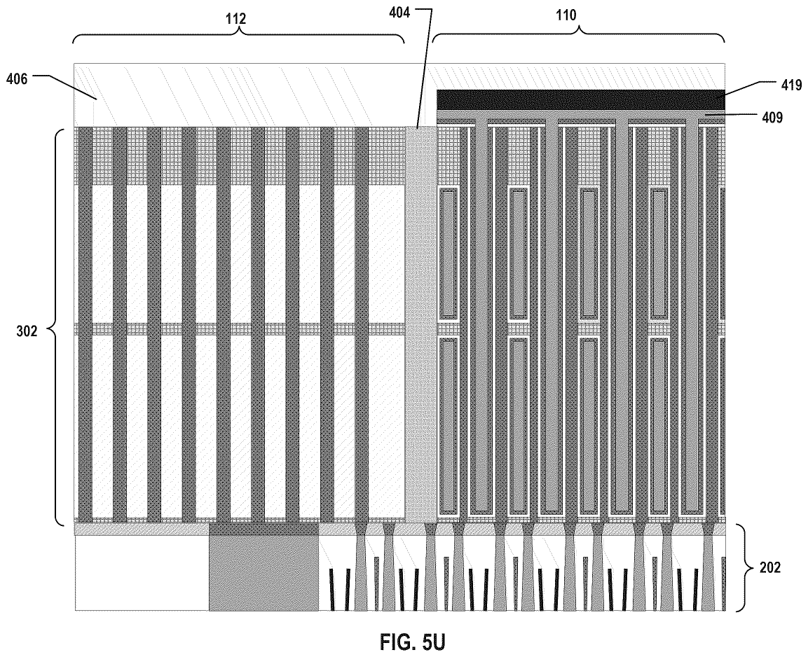

An enlarged view of vertical capacitor 274 in the cross section of FIG. 4B is shown in FIG. 4C, where a dashed circle 493 illustrates a projection of a mesh opening 516 of FIG. 5M onto the cross section of FIG. 4B. Four vertical capacitors 274 are formed around mesh opening 516 (e.g., around the projection of mesh opening 516). In a cross section of first layer 304C perpendicular to the z-direction, second electrode structure 411 is located between first electrode structure 403 and another adjacent first electrode structure 403 in memory array region 110. For example, in the cross section of first layer 304C, second electrode structure 411 is formed in mesh opening 516. That is, second electrode structures 411 of the four vertical capacitors 274 around mesh opening 516 are formed in mesh opening 516.

In some implementations, first electrode structure 403 and/or second electrode structure 411 can include conductive materials including, but not limited to, W, Co, Cu, Al, TiN, TaN, polysilicon, silicide, or any combination thereof. In some implementations, first electrode structure 403 and/or second electrode structure 411 can include a single-layer structure or a multi-layer structure, with a layer of the multi-layer structure including one of TiN, TaN, carbon, polysilicon, metal, metal compounds, or silicide. For example, first electrode structure 403 can include a TiN layer or another suitable conductive layer. Alternatively, first electrode structure 403 can include a polysilicon layer and a TiN layer. Second electrode structure 411 can include a first conductive layer 407 (e.g., a TiN layer) and a second conductive layer 409 (e.g., a GeSi layer). A third conductive layer 419 (e.g., a W layer) may be deposited on second conductive layer 409. In some implementations, storage dielectric layer 405 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof.

As illustrated in FIGS. 4A-4B, memory device 400 may further include stack structure 302 in contact region 112 and an isolation structure 404 located between memory array region 110 and contact region 112. Isolation structure 404 may isolate the array of vertical capacitors 274 in memory array region 110 from stack structure 302 in contact region 112. Isolation structure 404 may include a first end in first layer 304C (e.g., the first end being away from the array of vertical transistors 172) and a second end in first layer 304A (e.g., the second end being close to the array of vertical transistors 172). Isolation structure 404 may include a dielectric material including, but not limited to, silicon nitride, silicon oxynitride, silicon carbon nitride (SiCN), silicon boron nitride (SiBN), or any combination thereof. The dielectric material of isolation structure 404 may be different from that of first dielectric layers 306, and may be different from or the same as that of first layers 304. As shown in FIG. 4B, isolation structure 404 may surround memory cell array 130.

Stack structure 302 may include alternating first layers 304 (e.g., 304A, 304B, 304C) and first dielectric layers 306 (e.g., 306A, 306B) in contact region 112. For example, stack structure 302 may include, from bottom to top, first layer 304A, first dielectric layer 306A, first layer 304B, first dielectric layer 306B, and first layer 304C. In some implementations, first dielectric layers 306 may include a first dielectric material, and first layers 304 may include second dielectric layers that include a second dielectric material. That is, first layers 304 are formed by the same second dielectric material. The first dielectric material may include, but is not limited to, silicon oxide, silicon nitride, silicon oxynitride, or any combination thereof. The second dielectric material may include, but is not limited to, silicon nitride, silicon oxynitride, silicon carbon nitride (SiCN), or silicon boron nitride (SiBN), or any combination thereof. The first dielectric material is different from the second dielectric material. For example, the first dielectric material may include silicon oxide. The second dielectric material may include silicon nitride, SiCN, or SiBN.

In some other implementations, first dielectric layers 306 may include the first dielectric material. First layers 304 may include at least (1) a second dielectric layer that includes a second dielectric material and (2) a third dielectric layer that includes a third dielectric material. For example, different first layers 304 may be formed with different dielectric materials. The third dielectric material may include, but is not limited to, silicon nitride, silicon oxynitride, SiCN, SiBN, or any combination thereof. The first dielectric material, the second dielectric material, and the third dielectric material are different dielectric materials. For example, the first dielectric material may include silicon oxide. The second dielectric material may include one of silicon nitride, SiCN, or SiBN, whereas the third dielectric material may include another one of silicon nitride, SiCN, or SiBN.

In one example, first dielectric layers 306A and 306B may include silicon oxide. First layer 304A may include silicon nitride or SiBN. First layer 304B may include SiCN. First layer 304C may include silicon nitride or SiCN.

As illustrated in FIGS. 4A-4B, first semiconductor structure 104 may further include a plurality of via structures 425 extending through stack structure 302 in contact region 112 in the vertical direction (e.g., the z-direction). Via structure 425 may include a first end in first layer 304C that is away from the array of vertical transistors 172 and a second end in first layer 304A that is close to the array of vertical transistors. An end surface of via structure 425 that is away from the array of vertical transistors 172 (e.g., a surface of the first end of via structure 425) is flush with an end surface of isolation structure 404 that is away from the array of vertical transistors 172 (e.g., a surface of the first end of isolation structure 404).

In some implementations, as shown in FIG. 4B, via structures 425 may include a first contact structure 402. First contact structure 402 may extend through stack structure 302 and transistor structure 202 to connect with peripheral circuit 132 as shown in FIG. 4D. For example, first contact structure 402 can be a through silicon contact. In some implementations, as shown in FIG. 4B, via structures 425 may further include a second contact structure 410 extending through stack structure 302 in contact region 112 in the z-direction and coupled to a word line (e.g., word line 166 of FIG. 1B). Via structures 425 may also include a third contact structure 408 extending through stack structure 302 in contact region 112 in the z-direction and coupled to a bit line (e.g., bit line 168 of FIG. 1B). Via structures 425 may also include a dummy structure 422 or other contact structures (e.g., contact structure 485 of FIG. 4D) in contact region 112. It is contemplated that the locations of dummy structure 422, first contact structure 402, second contact structure 410, and third contact structure 408 shown in FIG. 4B are for illustration purposes only, and these structures can be formed in any suitable locations within contact region 112.

In some implementations, the contact structure (e.g., 402, 408, 410, 485) can include a conductive material including, but not limited to, W, Co, Cu, Al, TiN, TaN, polysilicon, silicide, or any combination thereof. In some implementations, the contact structure can include a single-layer structure or a multi-layer structure, where a layer of the multi-layer structure may include one of TiN, TaN, carbon, polysilicon, metal, metal compounds, or silicide. For example, the contact structure can include a TiN layer or another suitable metal layer. Alternatively, the contact structure can include a polysilicon layer and a TiN layer.

Dummy structure 422 may include conductive material like that of contact structure 402, 408, 410, or 485. Alternatively, dummy structure 422 may include any other semiconductor material or a dielectric material including, but not limited to, silicon oxide, silicon nitride, silicon oxynitride, SiCN, SiBN, or any combination thereof. In some implementations, the dummy structure is not electrically connected to other structures. For example, the dummy structure is not connected to the source, drain or gate of a transistor. Dummy structure 422 may include (i) a first end in first layer 304C that is away from the array of vertical transistors 172 and (ii) a second end in first layer 304A that is close to the array of vertical transistors 172. An end surface of dummy structure 422 that is away from the array of vertical transistors 172 (e.g., a surface of the first end of dummy structure 422) is flush with the end surface of isolation structure 404 that is away from the array of vertical transistors 172 (e.g., the surface of the first end of isolation structure 404).

As described above with reference to FIGS. 4A-4C, vertical capacitor 274 may include first electrode structure 403 and second electrode structure 411 isolated from first electrode structure 403. First electrode structure 403 may include (i) a first end in first layer 304C that is away from the array of vertical transistors 172 and (ii) a second end in first layer 304A that is close to the array of vertical transistors. An end surface of first electrode structure 403 that is away from the array of vertical transistors 172 (e.g., a surface of the first end of first electrode structure 403) is flush with the end surface of isolation structure 404 that is away from the array of vertical transistors 172 (e.g., the surface of the first end of isolation structure 404). In some implementations, first electrode structure 403 and via structure 425 (e.g., contact structure 402, 408, 410, or dummy structure 422) may have a cylinder shape. A diameter of the end surface of first electrode structure 403 may be equal to a diameter of the end surface of via structure 425 (e.g., contact structure 402, 408, 410, or dummy structure 422).

With reference to FIG. 4A, isolation structure 404 may include isolation segments 454 in first layers 304 and isolation segments 456 in first dielectric layers 306, e.g., an isolation segment 454A in first layer 304A, an isolation segment 456A in first dielectric layer 306A (e.g., between first layers 304A and 304B), an isolation segment 454B in first layer 304B, an isolation segment 456B in first dielectric layer 306B (e.g., between first layers 304B and 304C), and an isolation segment 454C in first layer 304C. At least a part of a side wall of isolation structure 404 has a wavy shape. For example, with reference to FIG. 4E, in a cross section of first dielectric layer 306A or 306B perpendicular to the z-direction, isolation segment 456A or 456B of isolation structure 404 may include a first trench structure 458. A width 460 of first trench structure 458 is greater than the diameter of the end surface of first electrode structure 403. In some implementations, width 460 of first trench structure 458 is greater than n times of the diameter of the end surface of first electrode structure 403, where n is a positive number equal to or greater than 2. First trench structure 458 may have two wavy side walls 462A and 462B. Width 460 of first trench structure 458 may be, for example, a maximal width between the two wavy side walls 462A and 462B.

In another example, with reference to FIG. 4F, in a cross section of first layer 304A, 304B, or 304C perpendicular to the z-direction, isolation segment 454A, 454B, or 454C of isolation structure 404 may include a second trench structure 459. A width 464 of second trench structure 459 is greater than the diameter of the end surface of first electrode structure 403. In some implementations, width 464 of second trench structure 459 is greater than n times of the diameter of the end surface of first electrode structure 403, where n is a positive number equal to or greater than 2. Second trench structure 459 may have two wavy side walls 466A and 466B. Width 464 of second trench structure 459 may be, for example, a maximal width between the two wavy side walls 466A and 466B.

Alternatively, with reference to FIG. 4G, in a cross section of first layer 304A, 304B, or 304C perpendicular to the z-direction, isolation segment 454A, 454B, or 454C of isolation structure 404 may include one or more sets of separate isolation members 468, with each set of isolation members 468 surrounding memory array region 110. For example, each set of isolation members 468 may include a ring of isolation members 468 that surrounds memory array region 110. For illustration purposes only, two rings of isolation members 468 are shown in FIG. 4G. Isolation member 468 may have a cylinder shape. In some implementations, a diameter of isolation member 468 is equal to the diameter of the end surface of first electrode structure 403 (or the diameter of the end surface of dummy structure 422) that is away from transistor structure 202.

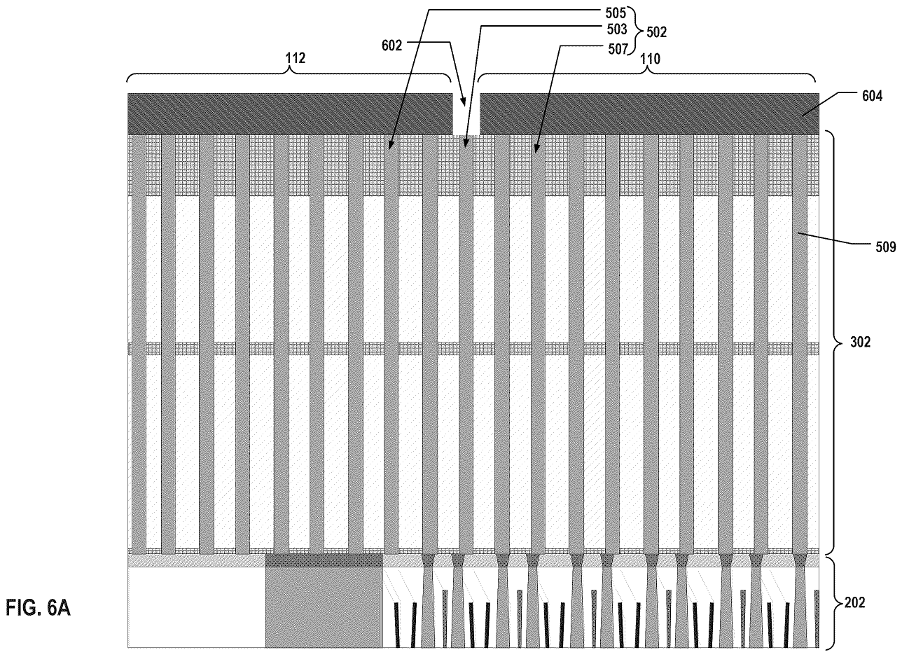

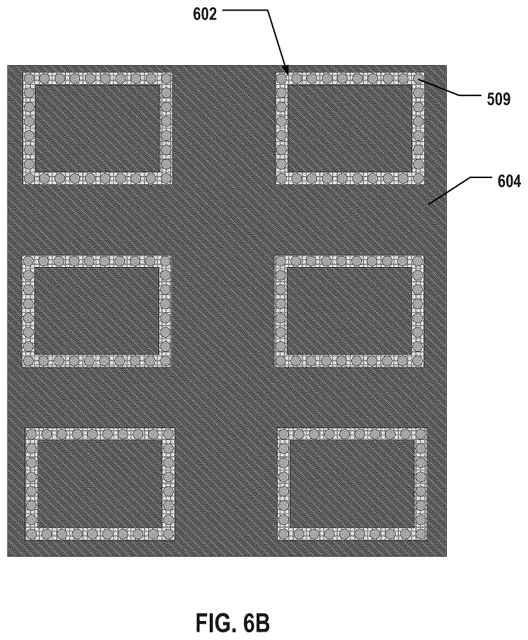

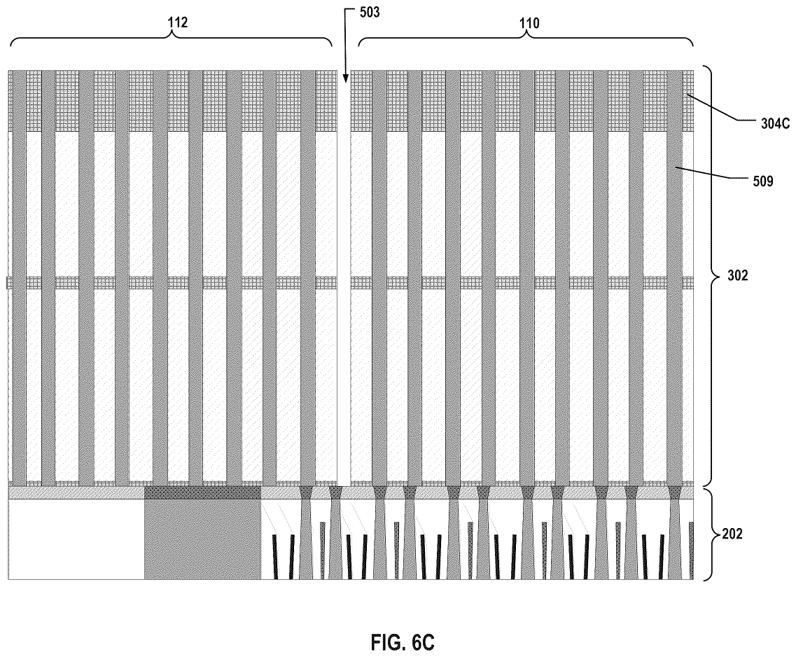

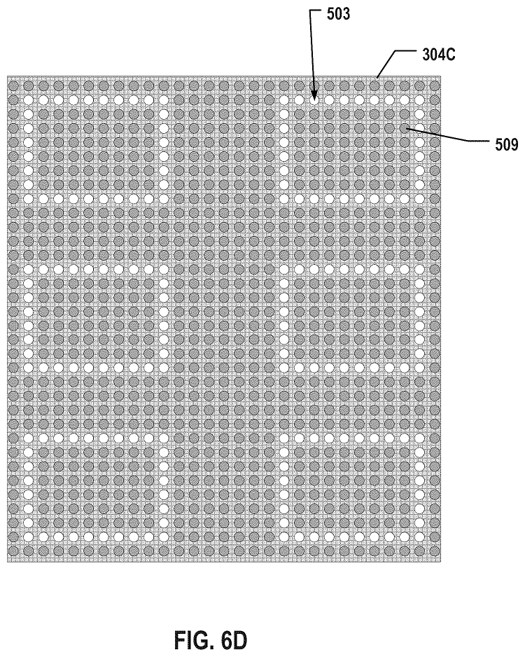

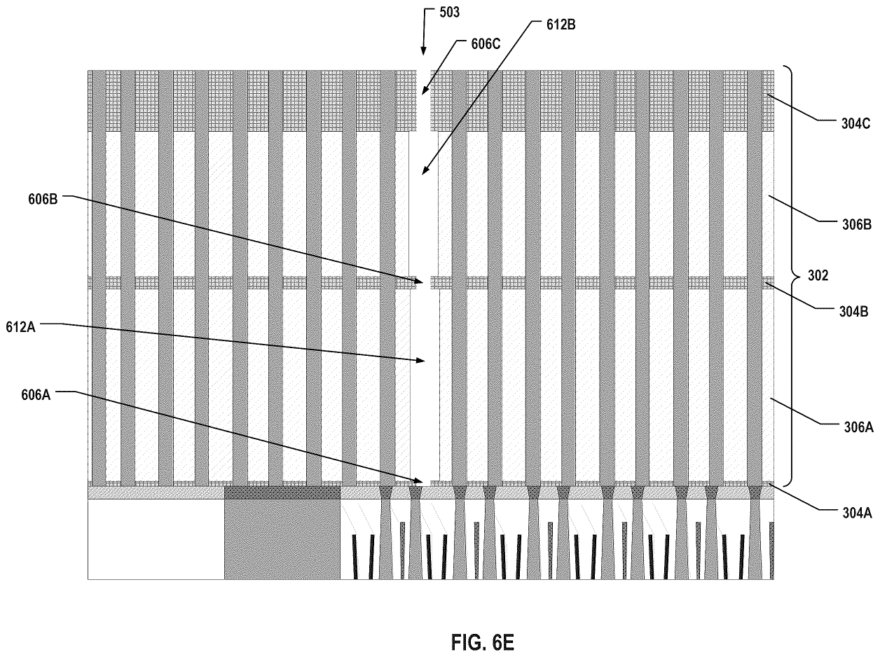

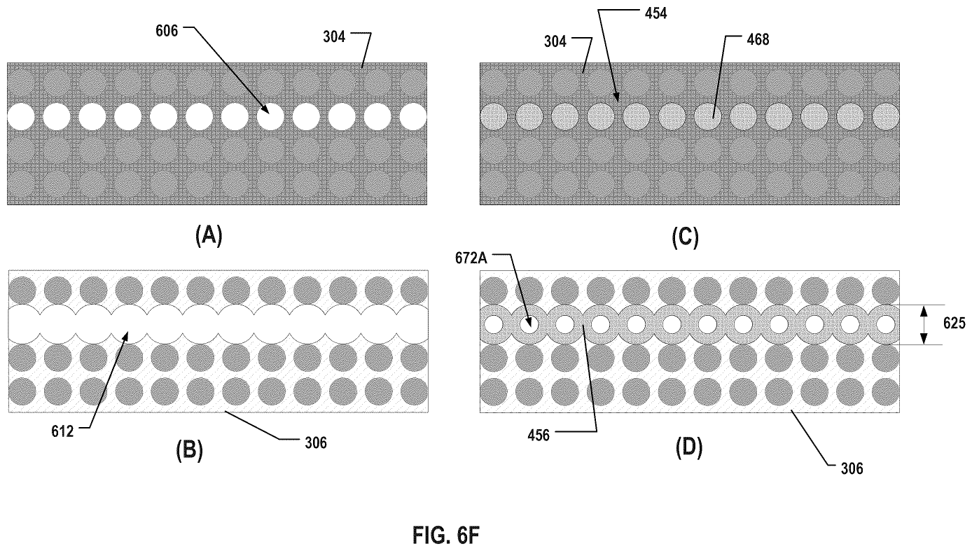

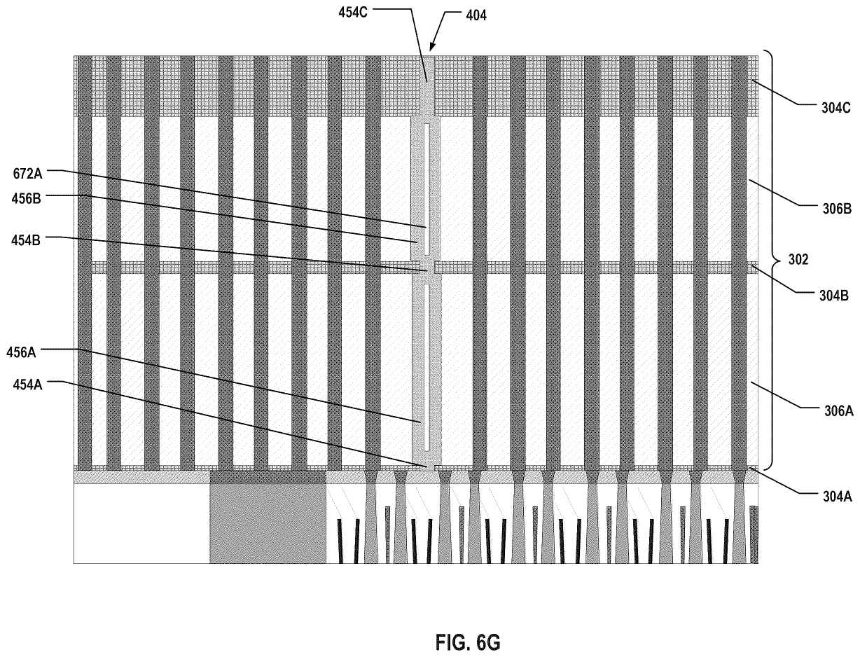

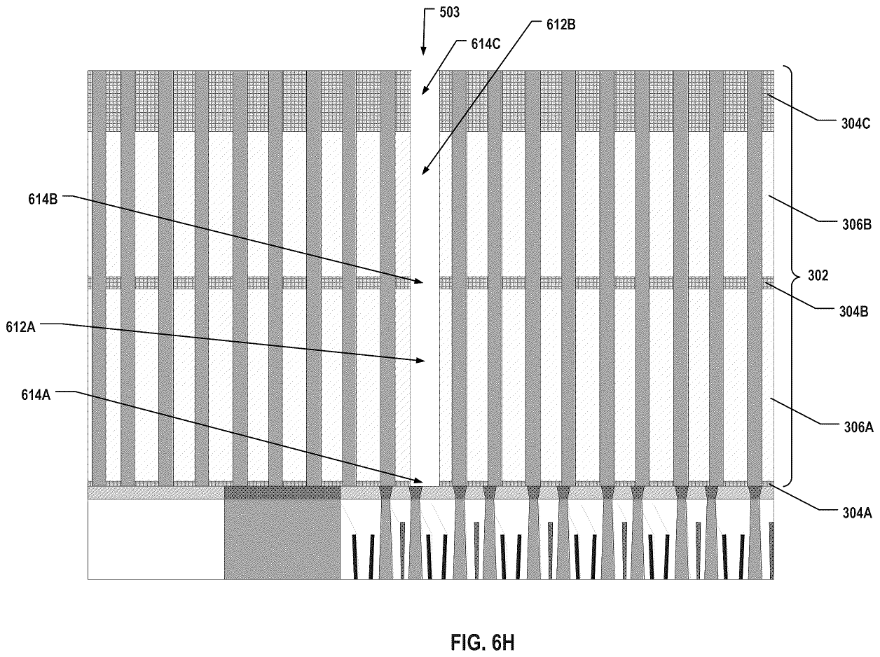

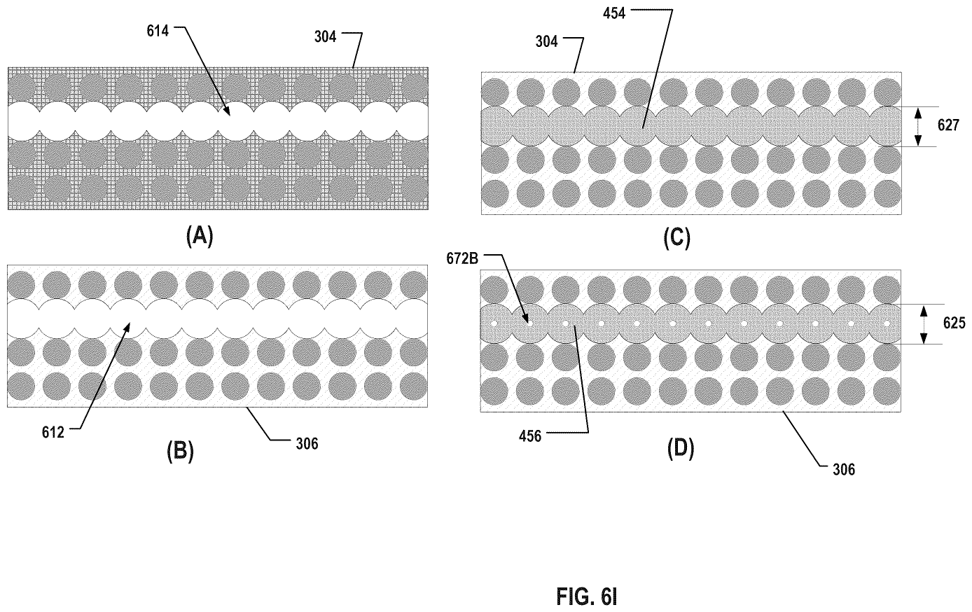

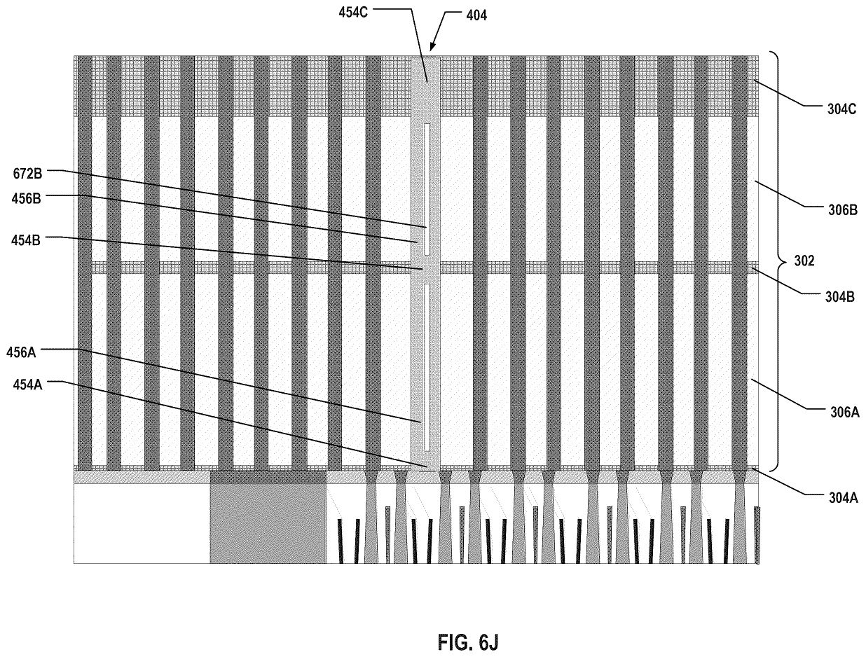

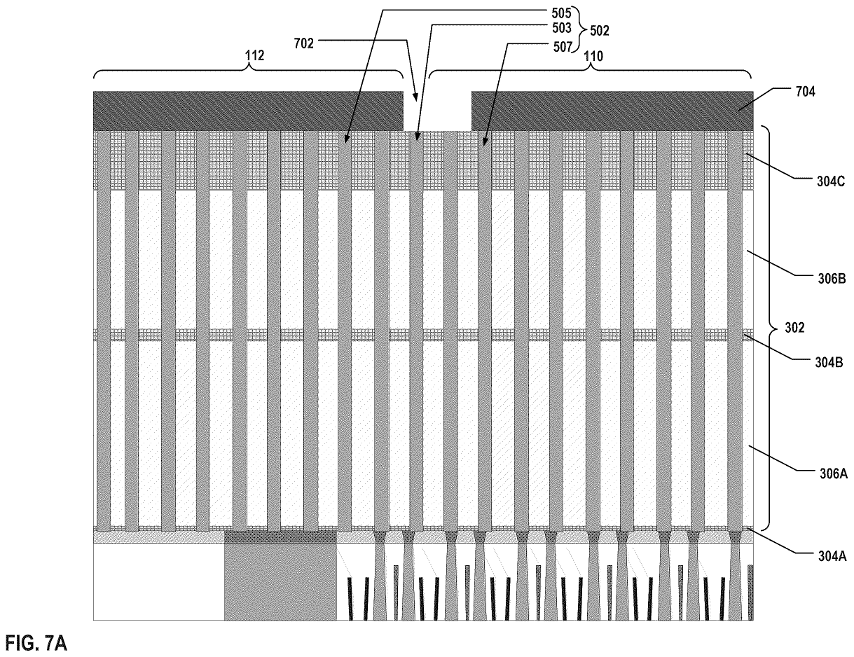

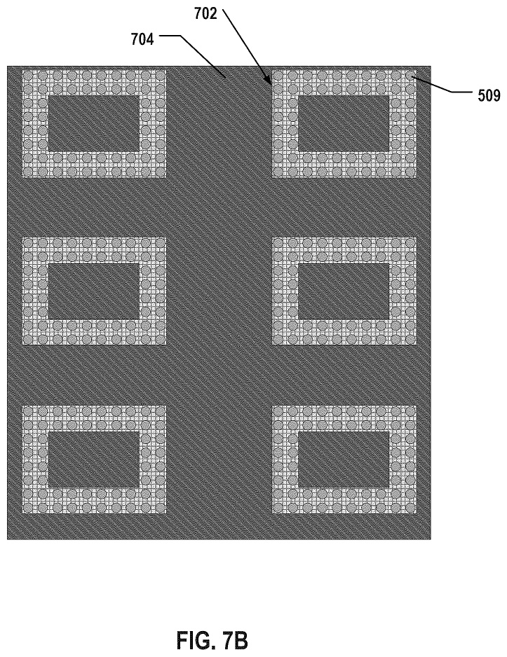

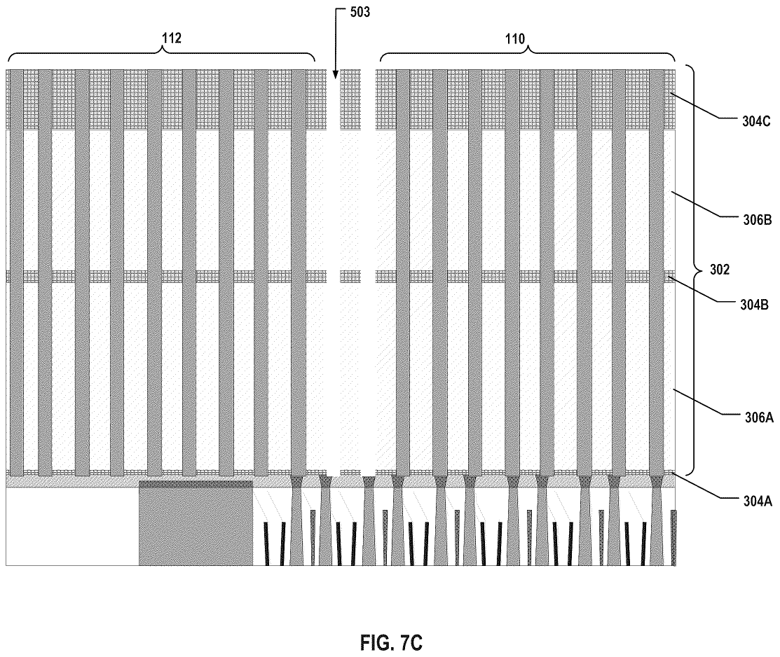

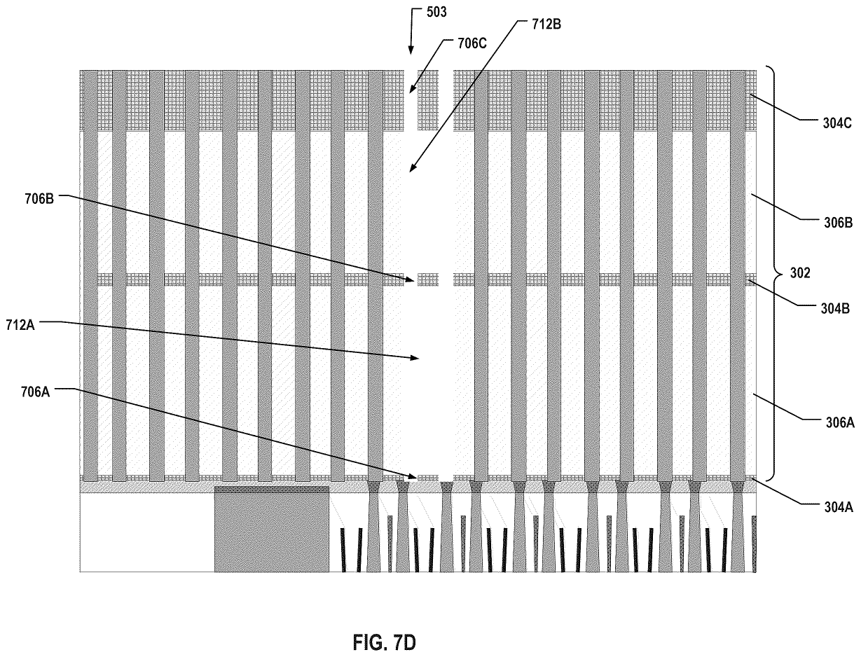

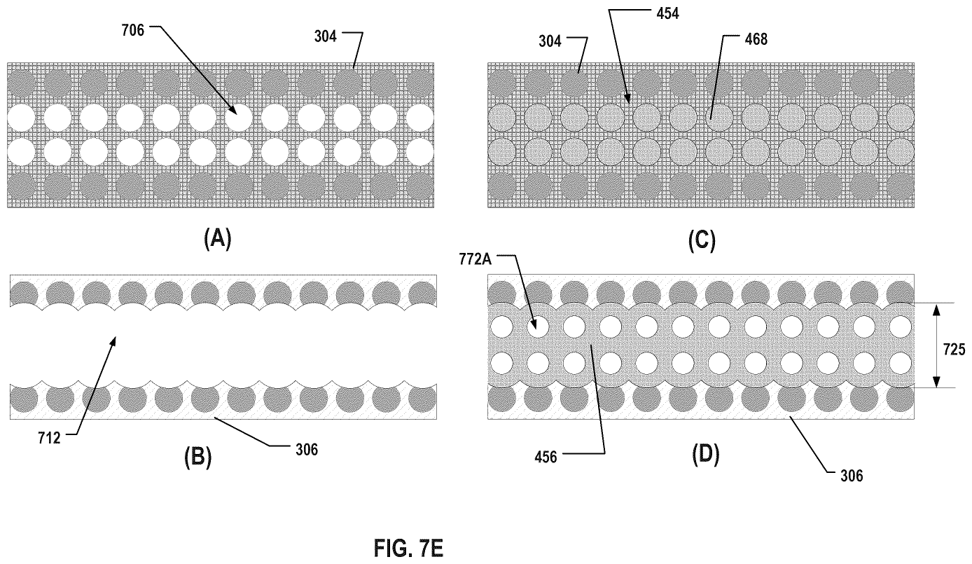

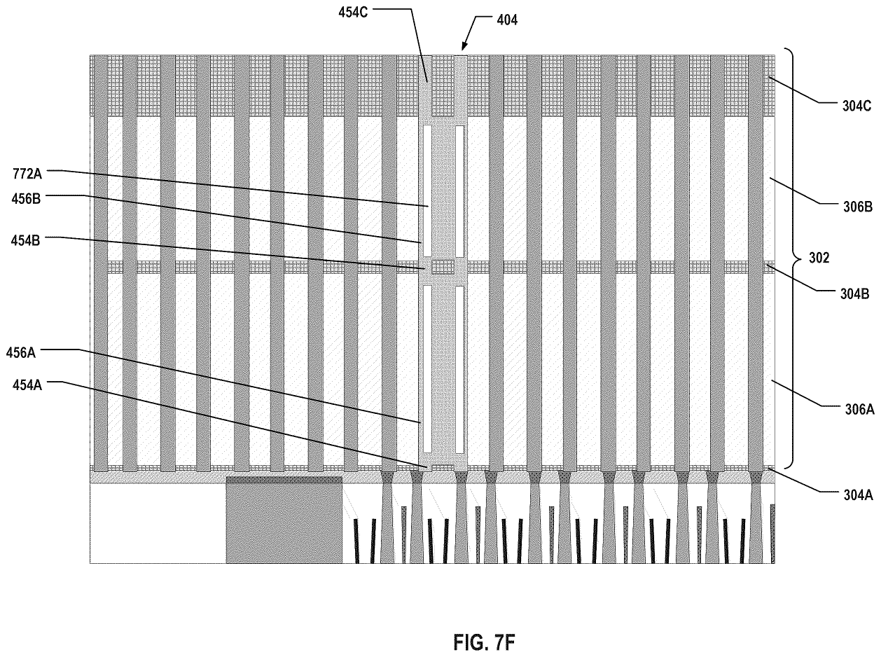

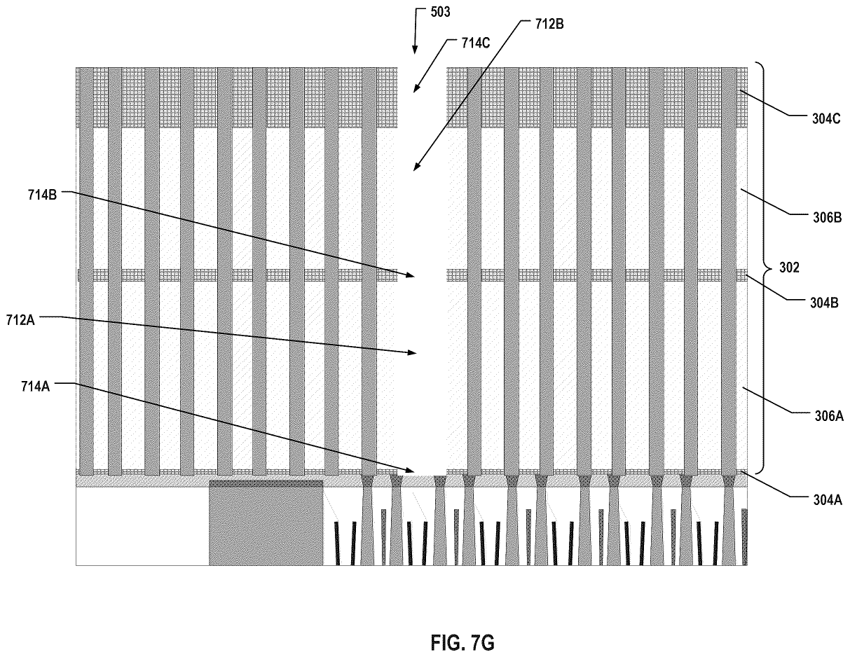

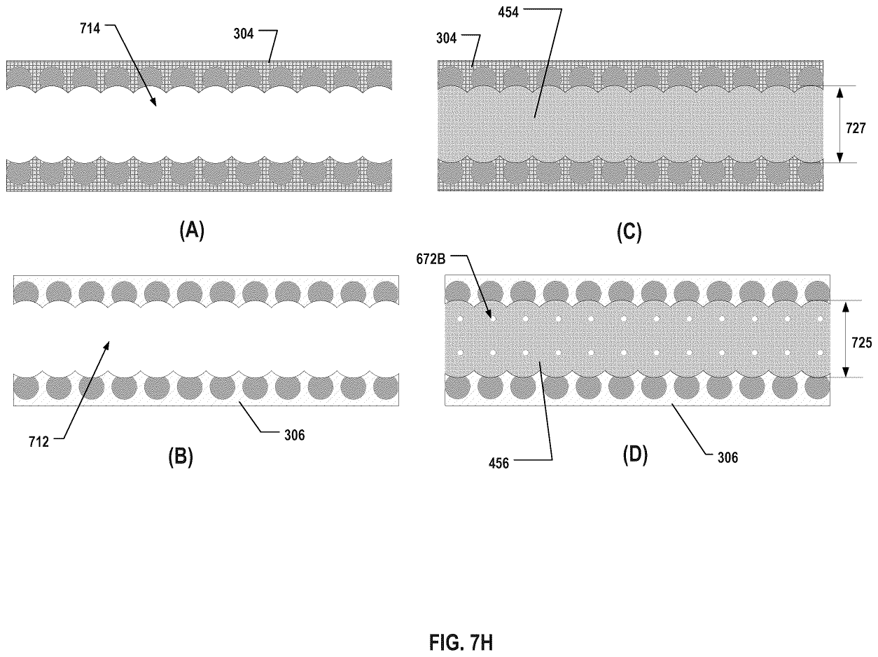

In some implementations, isolation segment 454A, 454B, or 454C in first layer 304A, 304B, or 304C may have the same dielectric material as first layer 304A, 304B, or 304C, respectively. As a result, boundaries of isolation segment 454A, 454B, or 454C in first layer 304A, 304B, or 304C may be invisible. In some implementations, isolation structure 404 may include at least a gap structure 672 or 772 (e.g., shown below in FIGS. 6F-6G, 6I-6J, 7E-7F, or 7H-7I). For example, gaps (e.g., air gaps) may be provided in isolation segment 456A or 456B in first dielectric layer 306A or 306B.

With reference to FIG. 4A, first semiconductor structure 104 may further include a dielectric layer 406 covering at least one of memory cell array 130 in memory array region 110, isolation structure 404, and/or stack structure 302 in contact region 112. Dielectric layer 406 may include a dielectric material including, but not limited to, silicon oxide, silicon nitride, silicon oxynitride, or any combination thereof.

In some implementations, memory device 400 can further include any other suitable components that are not illustrated in FIGS. 4A-4B. For example, in some implementations, memory device 400 can further include one or more interconnect layers including interconnect structures to electrically connect the word lines, the bit lines, the first and second electrode structures of the capacitors, etc., to transfer electrical signals. In some implementations, the one or more interconnect layers can include lateral interconnect lines and vertical interconnect access (VIA) contacts. In some implementations, the one or more interconnect layers can also include local interconnects, such as bit line contacts, word line contacts, and capacitor contacts. As used herein, the term “interconnects” can broadly include any suitable types of interconnects, such as middle-end-of-line (MEOL) interconnects and back-end-of-line (BEOL) interconnects. The one or more interconnect layers can further include one or more interlayer dielectric (ILD) layers (also known as “intermetal dielectric (IMD) layers”) in which the interconnect lines and via contacts can form. That is, the one or more interconnect layers can include interconnect lines and via contacts in multiple ILD layers. The interconnects in the one or more interconnect layers can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

FIG. 4D illustrates another side view of a cross section of memory device 400, according to some aspects of the present disclosure. The cross section in FIG. 4D may be along the B2-B2 line shown in FIG. 4B. It is understood that FIG. 4D is for illustrative purposes only and may not necessarily reflect the actual device structure (e.g., interconnections) in practice. As an example of 3D memory device 100 described above with respect to FIGS. 1A-1B, memory device 400 can be a bonded chip including first semiconductor structure 104 and second semiconductor structure 102, where first semiconductor structure 104 is stacked over second semiconductor structure 102. First and second semiconductor structures 104 and 102 are jointed at bonding interface 106 therebetween, according to some implementations. As shown in FIG. 4D, second semiconductor structure 102 can include a substrate 470, which can include silicon (e.g., single crystalline silicon, c-Si), SiGe, GaAs, Ge, SOI, or any other suitable materials.

Second semiconductor structure 102 can include peripheral circuits 132 on substrate 470. In some implementations, peripheral circuits 132 include a plurality of transistors 474 (e.g., planar transistors and/or 3D transistors). Trench isolations (e.g., shallow trench isolations (STIs)) and doped regions (e.g., wells, sources, and drains of transistors 474) can be formed on or in substrate 470 as well.

In some implementations, second semiconductor structure 102 further includes an interconnect layer 476 above peripheral circuits 132 to transfer electrical signals to and from peripheral circuits 132. Interconnect layer 476 can include a plurality of interconnects (also referred to herein as “contacts”), including lateral interconnect lines and VIA contacts. Interconnect layer 476 can further include one or more ILD layers in which the interconnect lines, via contacts, and bonding contacts can form. That is, interconnect layer 476 can include interconnect lines, via contacts, and bonding contacts in multiple ILD layers. In some implementations, peripheral circuits 132 are coupled to one another through the interconnects in interconnect layer 476. The interconnects in interconnect layer 476 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

First semiconductor structure 104 can be bonded on top of second semiconductor structure 102 in a face-to-face manner at bonding interface 106. In some implementations, bonding interface 106 is a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously.

In some implementations, first semiconductor structure 104 further includes an interconnect layer 481 including bit lines 482, interconnect lines, via contacts, and bonding contacts to transfer electrical signals. Interconnect layer 481 can include a plurality of interconnects, such as MEOL interconnects and BEOL interconnects. In some implementations, the interconnects in interconnect layer 481 also include local interconnects, such as bit lines 482 (e.g., an example of bit lines 168 in FIG. 1B) and word line contacts (not shown). Interconnect layer 481 can further include one or more ILD layers in which the interconnect lines and via contacts can form. The interconnects in interconnect layer 481 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof. In some implementations, peripheral circuits 132 include a word line driver/row decoder coupled to the word line contacts in interconnect layer 481 through interconnect lines, via contacts, and bonding contacts in interconnect layers 476 and 481. In some implementations, peripheral circuits 132 include a bit line driver/column decoder coupled to bit lines 482 and bit line contacts (if any) in interconnect layer 481 through interconnect lines, via contacts, and bonding contacts in interconnect layers 476 and 481.

In some implementations, first semiconductor structure 104 includes a DRAM device in which memory cells are provided in the form of an array of DRAM cells above interconnect layer 481. The array of DRAM cells is provided in memory array region 110. First contact structure 402, second contact structure 410 (not shown in FIG. 4D), third contact structure 408, contact structure 485, and dummy structure 422 are provided in contact region 112. Contact structure 485 may be coupled to second electrode structures 411 (e.g., the common electrode) of vertical capacitors 274 through third conductive layer 419. Isolation structure 404 is located between memory array region 110 and contact region 112 and surrounds memory array region 110.

The DRAM cell can include vertical transistor 172 and vertical capacitor 274 coupled to vertical transistor 172. In some implementations, one of source and drain (e.g., at the upper end in FIG. 4D) of vertical transistor 172 is coupled to vertical capacitor 274, and the other one of source and drain (e.g., at the lower end in FIG. 4D) of vertical transistor 172 is coupled to bit line 482.

FIGS. 5A-5U illustrate a fabrication process for forming memory device 400, according to some aspects of the present disclosure. Referring to FIGS. 5A and 5B (e.g., FIG. 5B is a plan view of the structure of FIG. 5A), transistor structure 202 including an array of vertical transistors 172 is formed. In some implementations, forming transistor structure 202 may include forming a plurality of semiconductor bodies 175 extending vertically on a semiconductor layer. In some implementations, the plurality of semiconductor bodies 175 can be formed by patterning a semiconductor substrate using any suitable patterning processes (e.g., photoetching, dry etching, wet etching, cleaning, chemical mechanical polishing (CMP), etc.) to form trenches laterally extending along the x-direction and the y-direction, the remaining vertical portions of the semiconductor substrate between the trenches form the semiconductor bodies 175, and the remaining lateral portion of the semiconductor substrate below the trenches form the semiconductor layer. In some implementations, TISO structures 513 can be formed in the trenches to laterally separate adjacent semiconductor bodies 175.

Semiconductor bodies 175 can be used to form channels of vertical transistors 172. In some implementations, semiconductor bodies 175 can be formed by using any suitable semiconductor material, such as monocrystalline silicon, polycrystalline silicon, or silicon-germanium. In some other implementations, semiconductor bodies 175 can be formed by using any suitable metal oxide semiconductor material, such as InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc.

In some implementations, gate structures of vertical transistors 172 can be formed. For example, forming a gate structure includes forming a gate dielectric layer and forming a gate electrode 176. In some implementations, the gate dielectric layer and gate electrode 176 can be formed by any suitable deposition processes (e.g., chemical vapor deposition (CVD), physical vapor deposition (PVD), atomic layer deposition (ALD), etc.). In some implementations, forming the gate dielectric layer can include depositing any suitable dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, forming gate electrode 176 includes depositing one or more layers of conductive materials including, but not limited to, W, Co, Cu, Al, TiN, TaN, polysilicon, silicide, or any combination thereof.

In some implementations, forming transistor structure 202 further includes forming insulating layer 439 to fill the trenches between adjacent gate structures and/or adjacent semiconductor bodies 175. In some implementations, forming transistor structure 202 further includes forming SNC structures 480 on top of semiconductor bodies 175, respectively.

Next, stack structure 302 is formed on transistor structure 202. Stack structure 302 may be formed by depositing alternating first layers 304 (304A, 304B, 304C) and first dielectric layers 306 (306A, 306B) on transistor structure 202 across memory array region 110 and contact region 112, using one or more thin film deposition processes including, but not limited to, CVD, PVD, ALD, or any combination thereof. First dielectric layers 306 may include the same dielectric material, whereas first layers 304 may include the same dielectric material or different dielectric materials. The dielectric material(s) of first layers 304 may be different from the dielectric material of first dielectric layers 306. For example, first dielectric layers 306A and 306B may include silicon oxide. First layer 304A may include silicon nitride (SiN) or SiBN. First layer 304B may include SiCN. First layer 304C may include SiN or SiCN.

Stack structure 302 may be etched to form openings 502 extending in the z-direction. Openings 502 may include one or more sets of first openings 503 between memory array region 110 and contact region 112, with each set of first openings 503 surrounding memory array region 110, at least a second opening 505 in contact region 112, an array of third openings 507 in memory array region 110, and/or other openings in contact region 112. In some implementations, fabrication processes for forming openings 502 in stack structure 302 include wet etching and/or dry etching, such as DRIE.

Referring to FIGS. 5C and 5D (e.g., FIG. 5D is a plan view of the structure of FIG. 5C), a sacrificial layer 509 may be deposited into openings 502 in stack structure 302. For example, sacrificial layer 509 different from first layers 304 and first dielectric layers 306, such as a polysilicon layer or a carbon layer, is deposited into openings 502 using one or more thin film deposition processes, such as CVD, PVD, ALD, or any combination thereof.

Referring to FIGS. 5E and 5F (e.g., FIG. 5F is a plan view of the structure of FIG. 5E), sacrificial layer 509 filled in the one or more sets of first openings 503 is removed to expose the one or more sets of first openings 503 using lithography and wet etching and/or dry etching. Isolation structure 404 can be formed in the one or more sets of first openings 503, by performing operations like those described below with reference to FIGS. 6A-6J or FIGS. 7A-7I.

Referring to FIGS. 5G and 5H (e.g., FIG. 5H is a plan view of the structure of FIG. 5G), sacrificial layer 509 filled in remaining openings 502 (e.g., second opening 505 and the array of third openings 507) shown in FIG. 5E may be removed using wet etching and/or dry etching to expose the remaining openings 502.

Referring to FIGS. 5I and 5J (e.g., FIG. 5J is a plan view of the structure of FIG. 5I), first electrode structures 403 of vertical capacitors 274 can be formed in the array of third opening 507; dummy structure 422 can be formed in second opening 505; and first contact structure 402, second contact structure 410, third contact structure 408, and any other contact structure may be formed in some of the remaining openings 502. It is contemplated that the locations of dummy structure 422, first contact structure 402, second contact structure 410, and third contact structure 408 shown in FIG. 5J are for illustration purposes only, and these structures can be formed in any suitable openings 502. In some implementations, first electrode structures 403 and dummy structure 422 may be formed by depositing one or more conductive layers into third openings 507 and second opening 505, respectively, using one or more thin film deposition processes such as CVD, PVD, ALD, or any combination thereof. Meanwhile, first contact structure 402, second contact structure 410, and third contact structure 408 may be formed by depositing the one or more conductive layers into corresponding remaining openings 502, respectively. For example, the one or more conductive layers may include a TiN layer.

Referring to FIGS. 5K and 5L (e.g., FIG. 5L is a plan view of the structure of FIG. 5K), a mesh hard mask 510 can be deposited on top of stack structure 302 of FIG. 5I. A photoresist layer 512 can be deposited on top of mesh hard mask 510. Photoresist layer 512 may be patterned to form openings 514 to expose mesh hard mask 510 through openings 514 in memory array region 110.

Referring to FIGS. 5M and 5N (e.g., FIG. 5N is a plan view of the structure of FIG. 5M), portions of mesh hard mask 510 exposed by photoresist layer 512 (shown in FIG. 5K) may be etched to expose first layer 304C. Then, the exposed portions of first layer 304C can be etched away to form first mesh openings 516 in memory array region 110 using wet etching and/or dry etching, such as DRIE. A portion of mesh hard mask 510 may also be removed.

Referring to FIG. 5O, a first part of first dielectric layer 306B in memory array region 110 can be removed through first mesh openings 516 to form a first recess 518 using wet etching and/or dry etching, such as DRIE. A remaining part of first dielectric layer 306B in contact region 112 is isolated by isolation structure 404 and remains intact.

Referring to FIG. 5P, using the remaining portion of mesh hard mask 510, portions of first layer 304B can also be etched away to form second mesh openings 520 in memory array region 110 using wet etching and/or dry etching, such as DRIE.

Referring to FIG. 5Q, a first part of first dielectric layer 306A in memory array region 110 can be removed through second mesh openings 520 to form a second recess 522 using wet etching and/or dry etching, such as DRIE. A remaining part of first dielectric layer 306A in contact region 112 is isolated by isolation structure 404 and remains intact. Therefore, a storage recess is formed in memory array region 110, which includes first meshing openings 516, first recess 518, second meshing openings 520, and second recess 522.

Referring to FIG. 5R, second electrode structures 411, which are isolated from first electrode structures 403 are formed in the storage recess at least by forming a storage dielectric layer 405 to cover first electrode structures 403 in the storage recess; and forming second electrode structures 411 in the storage recess by depositing a first conductive layer 407 (e.g., a TiN layer) and a second conductive layer 409 (e.g., a GeSi layer) over storage dielectric layer 405. For example, second electrode structures 411 can be formed by depositing a high-k dielectric layer to cover first electrode structures 403 and depositing a TiN layer and a GeSi layer over the high-k dielectric layer, using one or more thin film deposition processes such as CVD, PVD, ALD, or any combination thereof. Storage dielectric layer 405, first conductive layer 407, and second conductive layer 409 may extend across memory array region 110 and contact region 112 on top of stack structure 302. A third conductive layer 419 (e.g., a W layer) may also be formed over second conductive layer 409. Third conductive layer 419 may also extend across memory array region 110 and contact region 112.

Referring to FIGS. 5S and 5T (e.g., FIG. 5T is a plan view of the structure of FIG. 5S), a part of storage dielectric layer 405, a part of first conductive layer 407, a part of second conductive layer 409, and a part of third conductive layer 419, which are over stack structure 302 in contact region 112 and over isolation structure 404, may be etched away using dry etching and/or wet etching.

Referring to FIG. 5U, dielectric layer 406 may be formed by depositing a dielectric material (e.g., silicon oxide) across contact region 112 and memory array region 110 (e.g., over stack structure 302 in contact region 112, isolation structure 404, and third conductive layer 419 in memory array region 110), using one or more thin film deposition processes such as CVD, PVD, ALD, or any combination thereof. Chemical Mechanical Planarization (CMP) may be performed on dielectric layer 406.

FIGS. 6A-6J illustrate a fabrication process for forming isolation structure 404, according to some aspects of the present disclosure. The fabrication process of FIGS. 6A-6J follows FIGS. 5C-5D. After performing the operations described above with reference to FIGS. 5C-5D, openings 502 (including one or more sets of first openings 503, second opening 505, and the array of third openings 507) are filled by sacrificial layer 509. By way of examples, the fabrication process of FIGS. 6A-6J forms isolation structure 404 in a set of first openings 503. It is contemplated that isolation structure 404 can also be formed in more than one set of first openings 503 (e.g., two sets of first openings 503 as shown in FIGS. 7A-7I), which is not limited herein.

Referring to FIGS. 6A and 6B (e.g., FIG. 6B is a plan view of the structure of FIG. 6A), a photoresist layer 604 may be formed on top of stack structure 302 to cover stack structure 302. Photoresist layer 604 may be patterned and etched to form an opening 602 between memory array region 110 and contact region 112. Opening 602 may expose the end surfaces of the set of first openings 503 which are filled with sacrificial layer 509.

Referring to FIGS. 6C and 6D (e.g., FIG. 6D is a plan view of the structure of FIG. 6C), sacrificial layer 509 in the set of first openings 503 may be removed using dry etching and/or wet etching to expose the set of first openings 503. Photoresist layer 604 (shown in FIGS. 6A-6B) may also be removed.

A first example implementation of forming isolation structure 404 in the exposed set of first openings 503 (shown in FIGS. 6C and 6D) is illustrated in FIGS. 6E-6G. Referring to FIG. 6E and section (B) of FIG. 6F, in first dielectric layer 306 (306A or 306B), first portions of first openings 503 in the respective first dielectric layer 306 are merged to form a respective first trench opening 612 (612A or 612B). A side wall of the respective first trench opening 612 has a first wavy shape.

In some implementations, a part of the respective first dielectric layer 306 can be removed using dry etching and/or wet etching to expand (or enlarge) the first portions of first openings 503 in the respective first dielectric layer 306, such that the expanded (or enlarged) first portions of first openings 503 are merged to form the respective first trench opening 612 as shown in section (B) of FIG. 6F. For example, the respective first dielectric layer 306 may include silicon oxide, and hydrogen fluoride (HF) can be used to etch the respective first dielectric layer 306 to form the respective first trench opening 612 from the first portions of first openings 503 in the respective first dielectric layer 306.

Referring to FIG. 6E and section (A) of FIG. 6F, in first layer 304 (304A, 304B, 304C), second portions 606 (606A, 606B, or 606C) of first openings 503 in the respective first layer 304 remain intact.

Referring to section (C) of FIG. 6F and FIG. 6G, an isolation segment 454 (454A, 454B, or 454C) in the respective first layer 304 (304A, 304B, or 304C) may be formed in second portions 606 (606A, 606B, or 606C) of first openings 503 in the respective first layer 304. For example, separate isolation members 468 are formed in second portions 606 of first openings 503, respectively. Referring to section (D) of FIG. 6F and FIG. 6G, an isolation segment 456 (456A or 456B) in the respective first dielectric layer 306 (306A or 306B) may be formed in first trench opening 612 (612A or 612B) in the respective first dielectric layer 306. For example, a first trench structure may be formed in first trench opening 612 of the respective first dielectric layer 306. A width 625 of the first trench structure is greater than a diameter of an end surface of first electrode structure 403 that is away from the array of transistors 172. In some implementations, a gap structure 672A including one or more air gaps may be formed in the first trench structure.

In some implementations, the formation of isolation segment 454 in section (C) of FIG. 6F and isolation segment 456 in section (D) of FIG. 6F may be implemented by depositing a dielectric material into second portions 606 of first openings 503 and first trench opening 612, respectively, using one or more thin film deposition processes such as CVD, PVD, ALD, or any combination thereof. The dielectric material may include, but is not limited to, silicon nitride, silicon oxynitride, SiCN, SiBN, or any combination thereof.

A second example implementation of forming isolation structure 404 in the exposed set of first openings 503 (shown in FIGS. 6C and 6D) is illustrated in FIGS. 6H-6J. Referring to FIG. 6H and section (B) of FIG. 6I, in first dielectric layer 306 (306A or 306B), first portions of first openings 503 in the respective first dielectric layer 306 are merged to form a respective first trench opening 612 (612A or 612B), by performing operations like those described above with reference to FIG. 6E and section (B) of FIG. 6F. A side wall of the respective first trench opening 612 has a first wavy shape.

Referring to FIG. 6H and section (A) of FIG. 6I, in first layer 304 (304A, 304B, 304C), second portions of first openings 503 in the respective first layer 304 are merged to form a respective second trench opening 614 (614A, 614B, or 614C). A side wall of the respective second trench opening 614 has a second wavy shape. The second wavy shape may be the same as or different from the first wavy shape.

In some implementations, a part of the respective first layer 304 can be removed using dry etching and/or wet etching to expand (or enlarge) the second portions of first openings 503 in the respective first layer 304, such that the expanded (or enlarged) second portions of first openings 503 are merged to form the respective second trench opening 614 as shown in section (A) of FIG. 6I. For example, the respective first layer 304 may include SiCN, and phosphoric acid can be used to etch the respective first layer 304 to form the respective second trench opening 614 from the second portions of first openings 503 in the respective first layer 304.

Referring to section (C) of FIG. 6I and FIG. 6J, isolation segment 454 (454A, 454B, or 454C) in the respective first layer 304 (304A, 304B, or 304C) may be formed in second trench opening 614 of the respective first layer 304. For example, a second trench structure may be formed in second trench opening 614. A width 627 of the second trench structure is greater than the diameter of the end surface of first electrode structure 403 that is away from the array of transistors 172. Referring to section (D) of FIG. 6I and FIG. 6J, isolation segment 456 (456A or 456B) in the respective first dielectric layer 306 (306A or 306B) may be formed in first trench opening 612 in the respective first dielectric layer 306. For example, the first trench structure may be formed in first trench opening 612 of the respective first dielectric layer 306. In some implementations, a gap structure 672B including one or more air gaps may be formed in the first trench structure. Width 625 of the first trench structure is greater than the diameter of the end surface of first electrode structure 403 that is away from the array of transistors 172. The air gaps formed in gap structure 672B of FIG. 6I are smaller than the air gaps formed in gap structure 672A of FIG. 6F.

In some implementations, the formation of isolation segment 454 in section (C) of FIG. 6I and isolation segment 456 in section (D) of FIG. 6I may be implemented by depositing a dielectric material into second trench opening 614 and first trench opening 612, respectively, using one or more thin film deposition processes such as CVD, PVD, ALD, or any combination thereof. The dielectric material may include, but is not limited to, silicon nitride, silicon oxynitride, SiCN, SiBN, or any combination thereof.

FIGS. 7A-7I illustrate another fabrication process for forming isolation structure 404, according to some aspects of the present disclosure. Similar to the fabrication process of FIGS. 6A-6J, the fabrication process of FIGS. 7A-7I follows FIGS. 5C-5D. After performing the operations described above with reference to FIGS. 5C-5D, openings 502 (including one or more sets of first openings 503, second opening 505, and the array of third openings 507) are filled by sacrificial layer 509. By way of examples, the fabrication process of FIGS. 7A-7I forms isolation structure 404 in two sets of first openings 503.

Referring to FIGS. 7A and 7B (e.g., FIG. 7B is a plan view of the structure of FIG. 7A), a photoresist layer 704 may be formed on top of stack structure 302 to cover stack structure 302. Photoresist layer 704 may be patterned and etched to form an opening 702 between memory array region 110 and contact region 112. Opening 702 may expose the end surfaces of two sets of first openings 503 which are filled with sacrificial layer 509.

Referring to FIG. 7C, sacrificial layer 509 in the two sets of first openings 503 may be removed using dry etching and/or wet etching to expose the two sets of first openings 503. Photoresist layer 704 (shown in FIGS. 7A-7B) may also be removed.

A first example implementation of forming isolation structure 404 in the exposed sets of first openings 503 (shown in FIGS. 7C and 7D) is illustrated in FIGS. 7D-7F. Referring to FIG. 7D and section (B) of FIG. 7E, in first dielectric layer 306 (306A or 306B), first portions of first openings 503 in the respective first dielectric layer 306 are merged to form a respective first trench opening 712 (712A or 712B). A side wall of the respective first trench opening 712 has a first wavy shape.

In some implementations, a part of the respective first dielectric layer 306 can be removed using dry etching and/or wet etching to expand (or enlarge) the first portions of first openings 503 in the respective first dielectric layer 306, such that the expanded (or enlarged) first portions of first openings 503 are merged to form the respective first trench opening 712 as shown in section (B) of FIG. 7E. For example, the respective first dielectric layer 306 may include silicon oxide, and hydrogen fluoride (HF) can be used to etch the respective first dielectric layer 306 to form the respective first trench opening 712 from the first portions of first openings 503 in the respective first dielectric layer 306.

Referring to FIG. 7D and section (A) of FIG. 7E, in first layer 304 (304A, 304B, 304C), second portions 706 (706A, 706B, or 706C) of first openings 503 in the respective first layer 304 remain intact.

Referring to section (C) of FIG. 7E and FIG. 7F, isolation segment 454 (454A, 454B, or 454C) in the respective first layer 304 (304A, 304B, or 304C) may be formed in second portions 706 (706A, 706B, or 706C) of first openings 503 in the respective first layer 304. For example, separate isolation members 468 are formed in second portions 706 of first openings 503, respectively.

Referring to section (D) of FIG. 7E and FIG. 7F, isolation segment 456 (456A or 456B) in the respective first dielectric layer 306 (306A or 306B) may be formed in first trench opening 712 in the respective first dielectric layer 306. For example, a first trench structure may be formed in first trench opening 712 of the respective first dielectric layer 306. A width 725 of the first trench structure is greater than twice of the diameter of the end surface of first electrode structure 403 that is away from the array of transistors 172. In some implementations, a gap structure 772A including one or more air gaps may be formed in the first trench structure.

In some implementations, the formation of isolation segment 454 in section (C) of FIG. 7E and isolation segment 456 in section (D) of FIG. 7E may be implemented by depositing a dielectric material into second portions 706 of first openings 503 and first trench opening 712, respectively, using one or more thin film deposition processes such as CVD, PVD, ALD, or any combination thereof. The dielectric material may include, but is not limited to, silicon nitride, silicon oxynitride, SiCN, SiBN, or any combination thereof.

A second example implementation of forming isolation structure 404 in the exposed sets of first openings 503 (shown in FIG. 7C) is illustrated in FIGS. 7G-7I. Referring to FIG. 7G and section (B) of FIG. 7H, in first dielectric layer 306 (306A or 306B), first portions of first openings 503 in the respective first dielectric layer 306 are merged to form a respective first trench opening 712 (712A or 712B), by performing operations like those described above with reference to FIG. 7D and section (B) of FIG. 7E. A side wall of the respective first trench opening 712 has a first wavy shape.

Referring to FIG. 7G and section (A) of FIG. 7H, in first layer 304 (304A, 304B, 304C), second portions of first openings 503 in the respective first layer 304 are merged to form a respective second trench opening 714 (714A, 714B, or 714C). A side wall of the respective second trench opening 714 has a second wavy shape. The second wavy shape may be the same as or different from the first wavy shape.

In some implementations, a part of the respective first layer 304 can be removed using dry etching and/or wet etching to expand (or enlarge) the second portions of first openings 503 in the respective first layer 304, such that the expanded (or enlarged) second portions of first openings 503 are merged to form the respective second trench opening 714 as shown in section (A) of FIG. 7H. For example, the respective first layer 304 may include SiCN, and phosphoric acid can be used to etch the respective first layer 304 to form the respective second trench opening 714 from the second portions of first openings 503 in the respective first layer 304.

Referring to section (C) of FIG. 7H and FIG. 7I, isolation segment 454 (454A, 454B, or 454C) in the respective first layer 304 (304A, 304B, or 304C) may be formed in second trench opening 714 of the respective first layer 304. For example, a second trench structure may be formed in second trench opening 714. A width 727 of the second trench structure is greater than twice of the diameter of the end surface of first electrode structure 403 that is away from the array of transistors 172.

Referring to section (D) of FIG. 7H and FIG. 7I, isolation segment 456 (456A or 456B) in the respective first dielectric layer 306 (306A or 306B) may be formed in first trench opening 712 in the respective first dielectric layer 306. For example, a first trench structure may be formed in first trench opening 712 of the respective first dielectric layer 306. Width 725 of the first trench structure is greater than twice of the diameter of the end surface of first electrode structure 403 that is away from the array of transistors 172. In some implementations, a gap structure 772B including one or more air gaps may be formed in the first trench structure. The air gaps formed in gap structure 772B of FIG. 7H are smaller than the air gaps formed in gap structure 772A of FIG. 7E.

In some implementations, the formation of isolation segment 454 in section (C) of FIG. 7H and isolation segment 456 in section (D) of FIG. 7H may be implemented by depositing a dielectric material into second trench opening 714 and first trench opening 712, respectively, using one or more thin film deposition processes such as CVD, PVD, ALD, or any combination thereof. The dielectric material may include, but is not limited to, silicon nitride, silicon oxynitride, SiCN, SiBN, or any combination thereof.

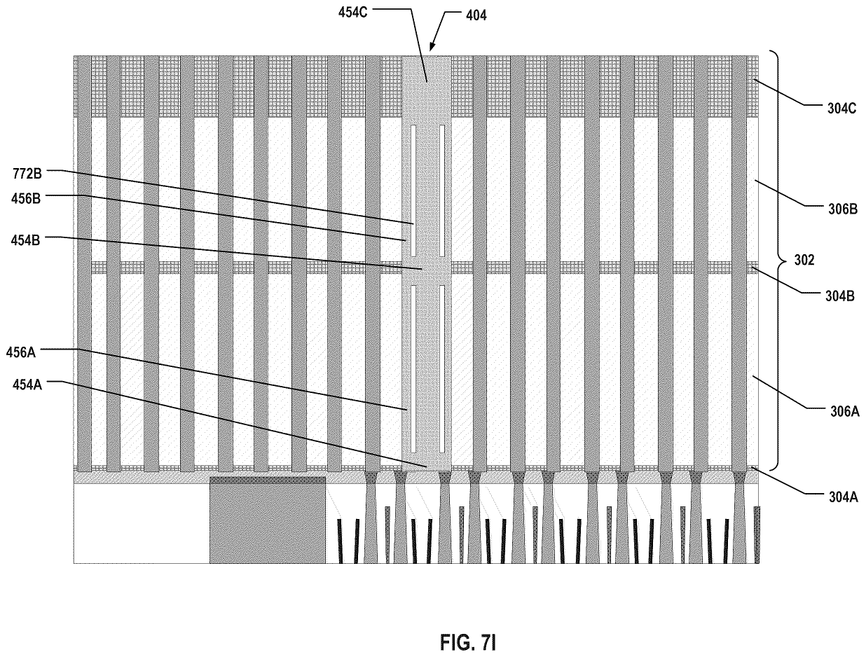

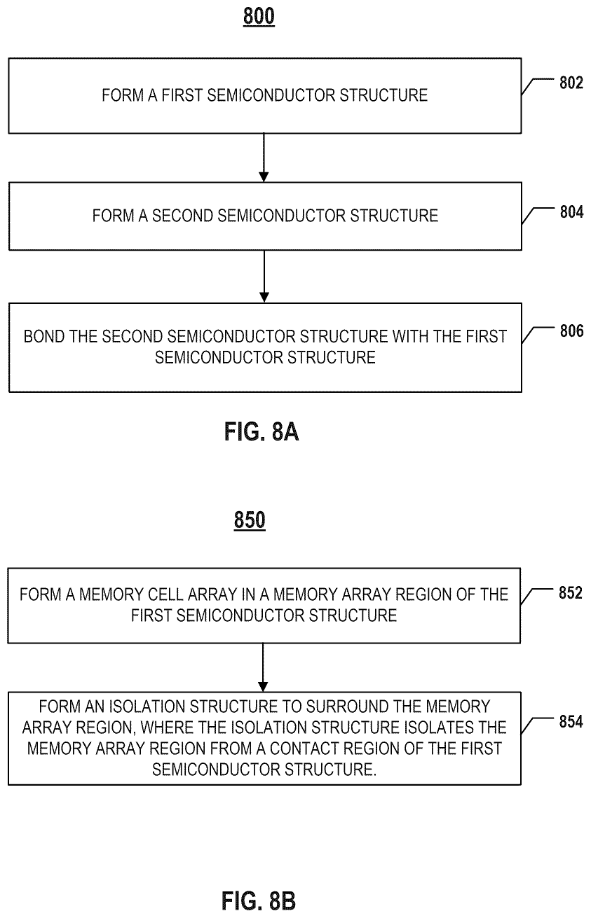

FIG. 8A illustrates a flowchart of a method 800 for forming a 3D memory device, according to some aspects of the present disclosure. The 3D memory device can be any memory device disclosed herein, such as memory device 100, 160, or 400. It is understood that the operations shown in method 800 are not exhaustive and that other operations can be performed as well before, after, or between any of the illustrated operations. Further, some of the operations may be performed simultaneously, or in a different order than shown in FIG. 8A.

As shown in FIG. 8A, method 800 can start at operation 802, in which a first semiconductor structure can be formed. For example, first semiconductor structure 104 can be formed by performing operations like those described above with reference to FIGS. 5A-5U.

As shown in FIG. 8A, method 800 can proceed to operation 804, in which a second semiconductor structure can be formed. In some implementations, second semiconductor structure 102 of FIG. 1A or FIG. 4D can be formed. For example, with reference to FIG. 4D, peripheral circuits 132 can be formed on substrate 470. Interconnect layer 476 may be formed above peripheral circuits 132 to transfer electrical signals to and from peripheral circuits 132.

As shown in FIG. 8A, method 800 can proceed to operation 806, in which the second semiconductor structure can be bonded with the first semiconductor structure. For example, as shown in FIG. 4D, first semiconductor structure 104 and second semiconductor structure 102 can be bonded using hybrid bonding.

FIG. 8B illustrates a flowchart of a method 850 for forming a first semiconductor structure (e.g., first semiconductor structure 104), according to some aspects of the present disclosure. It is understood that the operations shown in method 850 are not exhaustive and that other operations can be performed as well before, after, or between any of the illustrated operations. Further, some of the operations may be performed simultaneously, or in a different order than shown in FIG. 8B.

As shown in FIG. 8B, method 850 can start at operation 852, in which a memory cell array can be formed in a memory array region of the first semiconductor structure. For example, an array of transistors can be formed in the memory array region. An array of storage units which connect to corresponding transistors can be formed in memory array region.

As shown in FIG. 8B, method 850 can proceed to operation 854, in which an isolation structure can be formed to surround the memory array region. The isolation structure may isolate the memory array region from a contact region of the first semiconductor structure. For example, the isolation structure isolates the array of storage units in the memory array region from the contact region.

In some implementations, forming the first semiconductor structure in method 850 further includes forming a stack structure including alternating first layers and first dielectric layers across the memory array region and the contact region. For example, stack structure 302 including alternating first layers 304 and first dielectric layers 306 can be formed by performing operations like those described above with reference to FIG. 5A.

In some implementations, forming the first semiconductor structure in method 850 further includes forming openings extending through the stack structure in a first direction. The openings include one or more sets of first openings between the memory array region and the contact region, with each set of first openings surrounding the memory array region, a second opening in the contact region, and an array of third openings in the memory array region. For example, with reference to FIG. 5A, openings 502 may be formed to extend through stack structure 302 in the z-direction. Openings 502 include one or more sets of first openings 503, second opening 505 in contact region 112, and an array of third openings 507 in memory array region 110.

In some implementations, forming the isolation structure in operation 854 includes forming the isolation structure in the one or more sets of first openings. For example, as shown in FIG. 5E, isolation structure 404 is formed in the one or more sets of first openings 503.

In some implementations, forming the isolation structure in the one or more sets of first openings includes in at least a first dielectric layer from the first dielectric layers, merging first portions of the first openings in the first dielectric layer to form a first trench opening, where a side wall of the first trench opening has a first wavy shape; and forming a first trench structure in the first trench opening of the first dielectric layer. For example, as shown in FIGS. 6E-6G, FIGS. 6H-6J, FIGS. 7D-7F, or FIGS. 7G-7I, first trench opening 612 or 712 may be formed in first dielectric layer 306, and a first trench structure (e.g., an example implementation of isolation segment 456) may be formed in first trench opening 612 or 712.

In some implementations, forming the isolation structure in the one or more sets of first openings further includes in at least a first layer from the first layers, forming separate isolation members in second portions of the first openings in the first layer, respectively. For example, as shown in FIGS. 6E-6G or FIGS. 7D-7F, isolation members 468 of isolation segment 454 may be formed in the second portions 606 or 706 of first openings 503 in first layer 304, respectively.

In some implementations, forming the isolation structure in the one or more sets of first openings further includes in at least a first layer from the first layers, merging second portions of the first openings in the first layer to form a second trench opening, where a side wall of the second trench opening has a second wavy shape; and forming a second trench structure in the second trench opening of the first dielectric layer. For example, as shown in FIGS. 6H-6J or FIGS. 7G-7I, second trench opening 614 or 714 may be formed in first layer 304. A second trench structure (e.g., an example implementation of isolation segment 454) may be formed in second trench opening 614 or 714.

In some implementations, forming the first semiconductor structure further includes forming a dummy structure in the second opening. An end surface of the dummy structure that is away from the array of transistors is flush with an end surface of the isolation structure that is away from the array of transistors. For example, with reference to FIGS. 5G-5J, dummy structure 422 may be formed in second opening 505. An end surface of dummy structure 422 that is away from the array of transistor 172 is flush with an end surface of isolation structure 404 that is away from the array of transistors 172.

In some implementations, the storage units include vertical capacitors, and forming the array of storage units in the memory array region includes: forming first electrode structures in the third openings, respectively, where the first electrode structures are coupled with the transistors, respectively; and forming second electrode structures isolated from the first electrode structures. The vertical capacitor includes a corresponding first electrode structure and a corresponding second electrode structure. For example, with reference to FIGS. 5G-5J, first electrode structures 403 may be formed in the array of third openings 507. With reference to FIGS. 5K-5T, second electrode structures 411 may be formed in memory array region 110.

In some implementations, forming the second electrode structures isolated from the first electrode structures includes forming a storage recess in the memory array region; and forming the second electrode structures isolated from the first electrode structures in the storage recess.

For example, forming the storage recess in the memory array region includes forming a first mesh opening extending through the first one of the first layers in the memory array region; removing a first part of a first one of the first dielectric layers in the memory array region through the first mesh opening to form a first recess, where a remaining part of the first one of the first dielectric layers in the contact region is isolated by the isolation structure and remains intact; forming a second mesh opening extending through a second one of the first layers in the memory array region; and removing a part of a second one of the first dielectric layers in the memory array region through the second mesh opening to form a second recess, where a remaining part of the second one of the first dielectric layers in the contact region is isolated by the isolation structure and remains intact. The storage recess includes the first meshing opening, the first recess, the second meshing opening, and the second recess. In a further example, the storage recess may be formed by performing operations like those described above with reference to FIGS. 5K-5Q.

For example, forming the second electrode structures isolated from the first electrode structures includes forming a storage dielectric layer to cover the first electrode structures in the storage recess; and forming the second electrode structures in the storage recess by depositing conductive layers over the storage dielectric layer to fill the storage recess. In a further example, second electrode structures 411 may be formed by performing operations like those described above with reference to FIGS. 5R-5T.

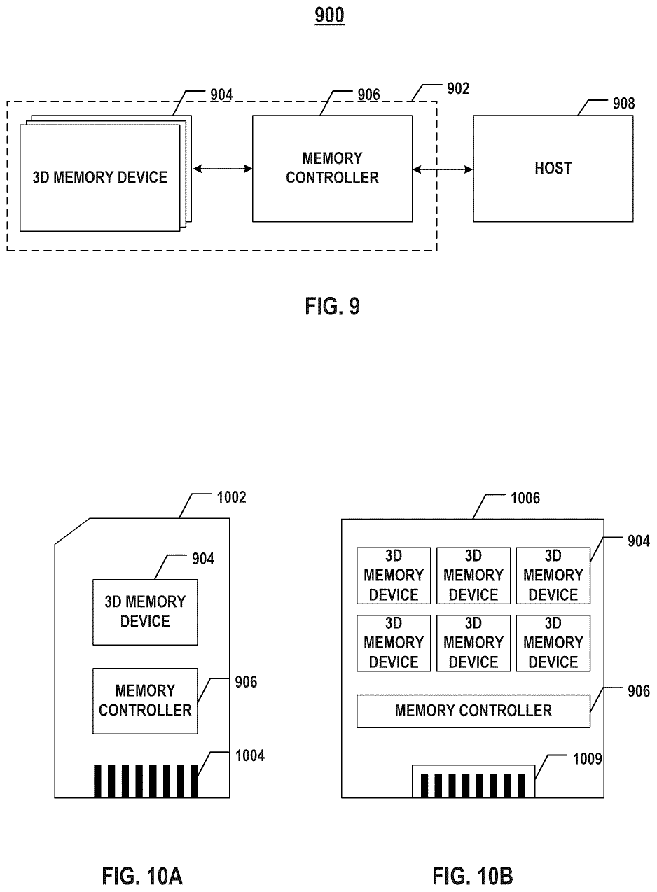

FIG. 9 illustrates a block diagram of an exemplary system 900 having a 3D memory device, according to some aspects of the present disclosure. System 900 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 9, system 900 can include a host 908 and a memory system 902 having one or more 3D memory devices 904 and a memory controller 906. Host 908 can be a processor of an electronic device, such as a central processing unit (CPU), or a system-on-chip (SoC), such as an application processor (AP). Host 908 can be configured to send or receive data to or from 3D memory devices 904.

3D memory device 904 can be any 3D memory device disclosed herein, such as 3D memory device 100 of FIG. 1A, memory device 160 of FIG. 1B, or memory device 400 of FIGS. 4A-4D. In some implementations, 3D memory device 904 includes a NAND Flash memory or a DRAM memory device.

Memory controller 906 (a.k.a., a controller circuit) is coupled to 3D memory device 904 and host 908 and is configured to control 3D memory device 904, according to some implementations. For example, memory controller 906 may be configured to operate the plurality of channel structures via the word lines. Memory controller 906 can manage the data stored in 3D memory device 904 and communicate with host 908. In some implementations, memory controller 906 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 906 is designed for operating in a high duty-cycle environment SSDs or embedded multi-media-cards (eMMCs) used as data storage for mobile devices, such as smartphones, tablets, laptop computers, etc., and enterprise storage arrays. Memory controller 906 can be configured to control operations of 3D memory device 904, such as read, erase, and program operations. Memory controller 906 can also be configured to manage various functions with respect to the data stored or to be stored in 3D memory device 904 including, but not limited to bad-block management, garbage collection, logical-to-physical address conversion, wear leveling, etc. In some implementations, memory controller 906 is further configured to process error correction codes (ECCs) with respect to the data read from or written to 3D memory device 904. Any other suitable functions may be performed by memory controller 906 as well, for example, formatting 3D memory device 904. Memory controller 906 can communicate with an external device (e.g., host 908) according to a particular communication protocol. For example, memory controller 906 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 906 and one or more 3D memory devices 904 can be integrated into various types of storage devices, for example, be included in the same package, such as a universal Flash storage (UFS) package or an eMMC package. That is, memory system 902 can be implemented and packaged into different types of end electronic products. In one example as shown in FIG. 10A, memory controller 906 and a single 3D memory device 904 may be integrated into a memory card 1002. Memory card 1002 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1002 can further include a memory card connector 1004 electrically coupling memory card 1002 with a host (e.g., host 908 in FIG. 9). In another example as shown in FIG. 10B, memory controller 906 and multiple 3D memory devices 904 may be integrated into an SSD 1006. SSD 1006 can further include an SSD connector 1009 electrically coupling SSD 1006 with a host (e.g., host 908 in FIG. 9). In some implementations, the storage capacity and/or the operation speed of SSD 1006 is greater than those of memory card 1002.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a first semiconductor structure comprising:
a memory cell array in a memory array region of the first semiconductor structure, comprising:
an array of transistors; and
an array of storage units which connect to corresponding transistors; and
an isolation structure surrounding the memory array region and isolating the array of storage units in the memory array region from a contact region of the first semiconductor structure.

2. The memory device of claim 1, wherein the first semiconductor structure further comprises:
a stack structure comprising alternating first layers and first dielectric layers in the contact region.

3. The memory device of claim 2, wherein the first dielectric layers comprise a first dielectric material, the first layers comprise second dielectric layers that comprise a second dielectric material, and the first dielectric material is different from the second dielectric material.

4. The memory device of claim 2, wherein:
the first dielectric layers comprise a first dielectric material;
the first layers comprise at least a second dielectric layer that comprises a second dielectric material and a third dielectric layer that comprises a third dielectric material; and
the first dielectric material, the second dielectric material, and the third dielectric material are different dielectric materials.

5. The memory device of claim 2, wherein the first semiconductor structure further comprises:
a dummy structure extending through the stack structure in the contact region in a first direction, wherein an end surface of the dummy structure that is away from the array of transistors is flush with an end surface of the isolation structure that is away from the array of transistors.

6. The memory device of claim 5, wherein the storage units comprise vertical capacitors, and the vertical capacitor comprises:
a first electrode structure coupled with a corresponding transistor; and
a second electrode structure isolated from the first electrode structure,
wherein an end surface of the first electrode structure that is away from the array of transistors is flush with the end surface of the dummy structure.

7. The memory device of claim 6, wherein a diameter of the end surface of the first electrode structure is equal to a diameter of the end surface of the dummy structure.

8. The memory device of claim 1, wherein at least a part of a side wall of the isolation structure has a wavy shape.

9. The memory device of claim 6, wherein:
in a cross section of one of the first dielectric layers perpendicular to the first direction,
the isolation structure comprises a first trench structure; and
a width of the first trench structure is greater than a diameter of the end surface of the first electrode structure.

10. The memory device of claim 9, wherein in a cross section of one of the first layers perpendicular to the first direction,
the isolation structure comprises one or more sets of separate isolation members with each set of isolation members surrounding the memory array region; and
a diameter of the isolation member is equal to the diameter of the end surface of the first electrode structure and the diameter of the end surface of the dummy structure.

11. The memory device of claim 9, wherein the width of the first trench structure is greater than n times of the diameter of the end surface of the first electrode structure, wherein n is a positive number equal to or greater than 2.

12. The memory device of claim 9, wherein:
in a cross section of one of the first layers perpendicular to the first direction,
the isolation structure comprises a second trench structure; and
a width of the second trench structure is greater than the diameter of the end surface of the first electrode structure.

13. The memory device of claim 12, wherein the width of the first trench structure and the width of the second trench structure are greater than n times of the diameter of the end surface of the first electrode structure, wherein n is a positive number equal to or greater than 2.

14. The memory device of claim 1, wherein the isolation structure comprises at least a gap structure.

15. The memory device of claim 6, wherein in a cross section of one of the first layers perpendicular to the first direction, the second electrode structure is located between the adjacent first electrode structures.

16. The memory device of claim 1, further comprising:
a second semiconductor structure bonded with the first semiconductor structure,
wherein the second semiconductor structure comprises a peripheral circuit coupled with the memory cell array.

17. A memory device, comprising:
a first semiconductor structure comprising:
a memory cell array in a memory array region of the first semiconductor structure, comprising:
an array of vertical transistors; and
an array of vertical capacitors which connect to corresponding vertical transistors; and
an isolation structure surrounding the memory array region and isolating the array of vertical capacitors in the memory array region from a contact region of the first semiconductor structure, wherein at least a part of a side wall of the isolation structure has a wavy shape.

18. A method for forming a memory device, comprising:
forming a first semiconductor structure at least by:
forming a memory cell array in a memory array region of the first semiconductor structure, comprising:
forming an array of transistors in the memory array region; and
forming, in the memory array region, an array of storage units which connect to corresponding transistors; and
forming an isolation structure to surround the memory array region, wherein the isolation structure isolates the array of storage units in the memory array region from a contact region of the first semiconductor structure.

19. The method of claim 18, wherein forming the first semiconductor structure further comprises:
forming a stack structure comprising alternating first layers and first dielectric layers across the memory array region and the contact region;
forming openings extending through the stack structure in a first direction,
wherein the openings comprise one or more sets of first openings between the memory array region and the contact region with each set of first openings surrounding the memory array region, a second opening in the contact region, and an array of third openings in the memory array region.

20. The method of claim 19, wherein forming the isolation structure comprises forming the isolation structure in the one or more sets of first openings at least by:
in at least a first dielectric layer from the first dielectric layers,
merging first portions of the first openings in the first dielectric layer to form a first trench opening, wherein a side wall of the first trench opening has a first wavy shape; and
forming a first trench structure in the first trench opening of the first dielectric layer.
